(19) United States
(12) Patent Application Publication
(10) Pub. No.: US 2024/0421570 A1
(43) Pub. Date: Dec. 19, 2024

(54) Segmented Rotary Cutting Head for Rotary Cable Processing Apparatuses and Method for Removing a Shielding Foil

(71) Applicant: Schleuniger AG, Thun (CH)

(72) Inventors: Raphael DESCHLER, Oberhofen (CH); Reto HOFER

(21) Appl. No.: 18/704,745

(22) PCT Filed: Oct. 26, 2022
(86) PCT No.: PCT/EP2022/079882

§ 371 Date: Apr. 25, 2024

(30) Foreign Application Priority Data
Oct. 27, 2021 (CH) 070456/2021

(51) Int. Cl. H02G 1/12

(52) U.S. Cl. CPC H02G 1/1265; H02G 1/1297

(57) ABSTRACT

The present invention relates to a rotary tool holding apparatus (1, 25, 39), comprising a rotor having a rotor base (2) consisting at least in part of an electrically conductive material, and comprising a segmented rotor end face (3), wherein at least a first rotor segment (6a) consisting at least in part of an electrically conductive material has one or more tool holding areas (5), wherein at least the first rotor segment (6a) is fastened to the rotor base (2) so as to be electrically insulated and is electrically insulated from at least some of the other rotor segments and is electrically connected to a device for detecting contact from an electrical conductor. The present invention also relates to a method for removing a shielding foil using a rotary tool holding apparatus according to the present invention.

### TECHNICAL FIELD OF THE INVENTION

The present invention concerns the technical field of cable processing apparatuses. The invention relates to a rotary tool holding apparatus with a rotor, a rotor base consisting at least in part of an electrically conductive material, as well as a segmented rotor end face, whereby at least a first rotor segment consisting at least in part of an electrically conductive material has one or more tool holding areas. The invention relates furthermore to an insulation stripping device and a method for removing a shielding foil with such a rotary tool holding apparatus.

### STATE OF THE ART

The production of pre-assembled electrical cables is a multi-stage process. It begins with cutting a continuous cable to length by cutting or sawing the cable and often ends with attaching a connector to the end of the cable, for example by crimping. Stripping the cable ends is a sub-step of this process. This stripping can itself comprise several stages. For example, at the end of a coaxial cable, a piece of the outer insulation sheath must be removed up to the outer shield. Furthermore, the insulation (a dielectric) between the inner conductor and the shield must be removed at the end of the cable before a connector can be fitted. Today's connectors are usually designed in such a way that the (stripped) inner conductor must protrude a little further than the (stripped) shield at the end of the cable.

For companies and factories that specialize in the production of prefabricated cables (for example, in the processing of shielded and unshielded cables for electromobility; 50 Ohm or 75 Ohm coaxial cables; power cables; computer connection cables; measuring and laboratory cables; and the like), it is preferable to use suitable machines instead of manual stripping processes, insofar as this is technically feasible. The purchase price and running costs of a stripping machine must be weighed up against the costs of (partial) manual processing. Irrespective of this, the relevant companies are generally inclined to give preference to automated processing, as today's stripping devices usually offer better quality in terms of the accuracy of the stripping length, as well as a lower probability of damage to the electrical conductors of the cable, such as in particular the damaging or cutting of individual shield or cable strands.

One problem to date is that a separate machine is often required for each type of cable and possibly even for each individual stripping step. At the very least, it is usually necessary to provide a separate machine for each task for different types of stripping-such as stripping the outer insulating sheath of coaxial cables, stripping the shielding foil, stripping the inner conductor of coaxial cables (removal of the dielectric), stripping the outer insulating sheath of three-core mains power cables, for example, and stripping the individual inner conductors of such mains power cables. This naturally calls for a correspondingly high capital requirement for the purchase of stripping devices. Unless particularly high quantities of prefabricated cables of one cable type are required, the procurement of specialized stripping devices quickly becomes unprofitable, as these can easily stand idle for significant periods of time until a new production requirement for a specific cable type or for a specific stripping step arises.

For example, European patent EP 2 976 818 B1 describes a stripping device that is particularly suitable for stripping a stranded cable using an oscillating circuit arrangement involving two cutting blades. However, this device does not have rotating tools, and is unsuitable for cleanly removing the shielding foil of a cable, for example.

The device presented in WO 2020/065366 A1 has rotating tools and a device for detecting contact between one of the tools and a conductive part of the cable. However, it was found that it is not possible to cleanly remove the shielding foil of a cable with rotating tools without regulating a controlled contact of the associated blade.

In contrast, the international patent application WO 2020/119960 A1 discloses a method and a suitable device for removing the outer insulation layer and for removing the shielding foil of a cable. The tools are pressed into the shielding foil in order to perforate the foil. Between two perforation steps, the blades are rotated around the cable. This process could also be carried out with the device of WO 2020/065366 A1. However, if all blades were arranged between two conductive plates as described, contact with a conductive part of the cable, in this case the shielding braid of the cable under the foil, would be detected by each of the tools, so that it would not be ensured that the foil was perforated evenly around the entire circumference. Accordingly, clean removal of the foil would not be guaranteed.

The same limitation exists in the device of the international patent application WO 2020/119916 A1, which discloses a cable stripping device with a stripping head having several tools whose radial distance to the axis of rotation of the stripping head can be adjusted by means of an adjusting means. Contact detection is provided between the blades and the electrical conductor of the cable to be stripped. However, this is not selective in relation to a specific blade, which would make it possible to regulate controlled contact with the associated blade. Adaptability to different stripping tasks is also not provided.

It would therefore be desirable to have a stripping machine that is as universal as possible and suitable for different stripping tasks, in particular for removing the insulation sheath and the shielding foil of a cable. It is usually acceptable if there is a certain amount of retooling when changing from one stripping task to another, as long as this can be carried out relatively easily and quickly by employees on site.

In this context, it should be noted that the availability of highly qualified personnel is often problematic nowadays. Accordingly, it is desirable to have the lowest possible minimum qualification level required for a person to carry out the changeover.

### SUMMARY OF INVENTION

According to the present invention, these objects are achieved above all through the elements according to the independent claims. Further advantageous embodiments emerge moreover from the dependent claims and the description.

In particular, the objects of the present invention are achieved by a rotary tool holding apparatus comprising a rotor having a rotor base of at least in part an electrically conductive material, and a segmented rotor end face, wherein at least a first rotor segment of at least in part an electrically conductive material comprises one or more tool holding areas, wherein at least the first rotor segment is fastened to the rotor base so as to be electrically insulated from the rotor base and is electrically insulated from at least some of the other rotor segments and wherein the first rotor segment is electrically connected to a device for detecting contact from an electrical conductor. Such a rotary tool holding apparatus can be used particularly advantageously for stripping an electrical cable with a longitudinal axis. For example, it can be used in a mode in which all tool holding areas are occupied with tools and all tools are electrically connected together. This is advantageous if the insulating sheath of a cable needs to be removed. In this case, it is advantageous if a large number of tools are available and each tool recognizes contact with an electrically conductive object, such as the cable shield.

In another mode, it is advantageous to provide only one tool, preferably the only sharp tool, that can detect contact with a conductor. This mode is particularly advantageous for removing a foil from a cable, since such a foil wrap is not perfectly round and therefore the foil must be perforated before removal using the blade-conductor contact detection.

In the case of rotary tool holding apparatuses, which are in principle particularly suitable for processing cable ends, especially cables with an essentially circular cross section, it makes sense to provide the rotary tool holding apparatus (typically including the tools accommodated therein) with an essentially n-count geometry, where n≥2, 3, 4, 5, 6, 7, 8, 9, 10, 11 or 12 typically applies. The n-count geometry usually refers to the presence or absence of tools; the tools themselves, on the other hand, can be designed differently and thus break the corresponding symmetry. For example, a cutting blade can be combined with a number of blunt blades, whereby the cable to be processed is subjected to a certain amount of force from different sides and does not tend to bend away due to the essentially symmetrical application of force. This allows the cable to be processed more efficiently. This can also be particularly effective in preventing any unbalance phenomena when turning the tool holding apparatus.

While an essentially symmetrical design makes sense with regard to certain aspects, such an at least electrically symmetrical design can prove to be problematic with regard to other aspects. For example, in some measuring and/or machining processes, it makes sense to enable angle-resolved machining or measurement. It is easy to see that the at least electrically symmetrical design described initially as advantageous is, on the contrary, disadvantageous. Depending on the specific application, however, there may also be other requirements with regard to electrical contacting. These inconsistencies have already been seen in the past, but no convincing solutions have been able to be proposed. For example, in the past, an electrically conductive tool was only used for a single tool holding area, while the remaining tool holding apparatuses were fitted with similarly shaped tools, although these had to be made from an electrically non-conductive material, such as ceramic. This was usually associated with high costs. With the proposed design, in which at least one of the tool holding areas is electrically insulated from the rotor base and the other tool holding areas, it is now possible, compared with a symmetrical design with an at least electrically asymmetrical construction, to detect the contact of only one tool with a conductive object, although a plurality, and possibly all, of the tool holding areas are equipped with tools that are electrically conductive (although this does not necessarily imply that the tools are identical; as already mentioned, for example, cutting blades can be combined with blunt blades). It is clear that this makes it possible to realize an overall more cost-effective design with a particularly high degree of variability and therefore high functionality. In principle, the electrically conductive material can be any material. However, metallic materials are advantageous. In particular, metallic materials (or generally electrically conductive materials) that are particularly suitable from a mechanical point of view for the intended use, such as e.g. steels, in particular tool steels (possibly with suitable alloy additives), copper, brass, aluminum and the like, can be considered. In particular, the tool holding areas can be tool holding areas that have suitable fastening devices for the arrangement of suitable tools. The tool holding areas and/or the fastening devices can be designed in such a way that they enable a substantially rigid fixing of the tools for some or all of the tools held. Alternatively, or additionally, it is also possible that the tool holding areas and the fastening devices are designed in such a way that the tools are only movable for some or all of the tools received. This movability can be passive (e.g. a certain amount of play), but in particular it can also be designed in such a way that a controlled movability of the tools is made possible depending on a certain control signal. The control signal can be applied in any form by mechanical, electrical, pneumatic, hydraulic or other means. The rotary tool holding apparatus is usually designed in such a way that it has a usually pronounced axial direction. The tool holding apparatus is often designed in such a way that it has a certain symmetry radially to the axial direction (in particular n-count symmetry, where n can be identical to the number of tool holding areas or a fraction thereof. The same applies to the number of rotor segments that may be present; a rotationally symmetrical design is also conceivable). The rotor end face and the rotor base are typically arranged in such a way that they follow one another in the axial direction. As a rule, the rotary tool holding apparatus has an axis of rotation or a connecting device for an axis of rotation along which the rotary tool holding apparatus can be set in a rotating motion. The rotating movement does not necessarily have to perform a rotary movement essentially always in one direction; it is instead also conceivable, for example, that a multiple back and forth movement is performed in relation to the direction of the rotational movement. A receiving opening is typically provided in the middle to receive the cable to be processed. This receiving opening can be continuous or be shaped like a blind hole or pocket. For the sake of completeness, it should be noted that while it is generally preferred that the tool holding areas have substantially similar angular widths, it may also be useful to use different angular widths and, in particular, to provide groups of different tool holding areas (e.g. a first group for cutting tools and a second group for hook tools or blunt blade tools). These groups of different tool holding areas can be combined in a rotor segment in particular (a rotor segment then has a number of different tool holding areas in particular; however, it is also conceivable that a rotor segment has a number of similar tool holding areas). It is possible that the tool holding areas within a rotor segment have different angular widths, but it is also possible that they have a (substantially) similar angular width. The individual rotor segments in turn preferably have a similar angular width. It should also be noted that it is generally particularly useful if a large part or all of the tool holding areas, but at least the differing rotor segments, are electrically insulated from one another and from the rotor base.

In a first preferred embodiment of the device according to the invention, electrical insulation is provided between the rotor base and at least some of the rotor segments and/or between at least some of the rotor segments themselves by means of an insulating layer which preferably comprises an electrically insulating material or is formed from an electrically insulating material and which particularly preferably comprises a plastic material or an adhesive material or is formed from a plastic material or from an adhesive material. As a rule, a particularly simple and cost-effective design can be realized in this way. In special cases in particular, however, it is also conceivable that a ceramic layer is provided. It is preferable if the insulating material or the plastic material is an impact-resistant or shock-resistant material. This proves to be particularly advantageous for the proposed application.

To ensure that the rotor segments and their associated tools are always electrically insulated from one another and from the rotor base, regardless of the position and number of tools fitted, it is advantageous if an insulating ring made of an electrically insulating material is provided in a central area of the rotary tool holding apparatus where the individual tool holding areas overlap (whereby this can also be designed as an insulating layer). Due to its material properties, PEEK (polyether ether ketone) is particularly suitable for the insulation ring, as this material is electrically well insulated, abrasion and pressure resistant and is easy to machine mechanically (together with the rotor segments). In addition, PEEK is also suitable for use at elevated temperatures in operation and for bonding with e.g. polyester resin at elevated temperatures (80 to 100° C.).

Instead of an insulating ring, the tool holding areas can also simply be recessed in those places where unwanted electrical contact between the blade and rotor segment is to be prevented. To avoid discontinuities such as steps in the tool holding area, which would prevent the blades from sliding or swiveling properly on the contact surface between the tools and tool holding areas, especially in connection with cable processing residues, it makes more sense to produce an entire ring as an insulating air gap, also for reasons of symmetry and production.

This solution is therefore similar to that with the insulating ring, but has the disadvantage that the blades are less well guided. However, since the blades are mainly subjected to forces in the direction of the cover plate when a cable sheath is removed, the reduced blade support is not a major disadvantage.

The use of glue material for bonding the rotor segments to the insulating layer or the insulating layer to the rotor base can prove to be advantageous, particularly from a process engineering point of view. For example, the area in question to be bonded can be provided with a layer of glue preferably 0.1 mm to 0.3 mm thick, preferably 0.15 mm to 0.25 mm thick, particularly preferably essentially 0.2 mm thick. The application of the glue layer and the positioning of any components/assemblies can be carried out in such a way that any air bubbles present in the glue material are pressed outwards (e.g. radially from the inside outwards) and/or any excess glue material can flow outwards. The use of adhesive layers can be particularly advantageous for the material-locking, mechanical fastening of parts to each other (which can be mechanically reinforced by further measures if necessary). Of course, it is also possible to use both plastic layers and glue layers (and possibly additionally or alternatively other electrically insulating layers) in combination. Prepreg fabrics, for example, can also be used as insulation and adhesive material, which can be glued together and to other objects (such as insulators, rotor segments or the rotor base) under pressure and heat.

In a further preferred embodiment of the device according to the invention, the device has a cover disk, preferably a disk-shaped cover disk, which covers the tool holding areas and has an electrically insulating material, the cover disk being configured such that it can be attached to the end face of the rotary tool holding apparatus in a first position in which the first rotor segment is electrically insulated from the other rotor segments. Such a cover disk can limit the degrees of freedom of the tools mounted on the rotor end face. This ensures that the tools do not come loose while the tool holding apparatus is in use. The cover disk also protects the setting mechanism, in particular the tool holding area and the elongated holes of the tools, from penetrating objects and provides personal protection, as there is no longer any direct access to the tool holding areas.

In another preferred embodiment of the device according to the invention, the cover disk has a metallic surface electrically connected to the rotor base on its side facing away from the rotor base. This allows the rotor segments, in particular the first rotor segment, to be electrically shielded. For this purpose, the cover disk has a metallic surface on its outer side (the side facing away from the rotor base), which is preferably brought into electrical contact with the rotor base with the aid of screws. Thanks to the metallic surface of the cover disk, the tools are protected from external influences, such as electric fields, which could falsify the detection of a contact between the tools and a conductive part of the cable.

In a further preferred embodiment of the device according to the invention, the cover disk is configured such that it can be attached to the end face of the rotary tool holding apparatus in a second position in which the cover disk electrically connects the first rotor segment to at least one of the other rotor segments. In this way, several or all rotor segments can be brought to the same electrical potential. The latter is advantageous if, for example, the insulating cable sheath has to be removed. In this case, it is advantageous if as many blades as possible can transmit pull-off forces and are connected to the device for detecting contact from an electrical conductor.

In a further preferred embodiment of the device according to the invention, the cover disk has on its side facing the rotor base at least one cover disk segment, preferably several cover disk segments with a metallic surface, wherein the cover disk segments are electrically insulated from one another and their angular extensions are designed in such a way that, at least in the first position of the cover disk, they do not cause any electrical contact from the first rotor segment to an adjacent rotor segment. As a result, the cover disk shields the rotor segments, including the blades, from the environment, because the cover disk segments are electrically connected to the rotor segments and cover the blades with the same electrical potential as the rotor segments, so that the blades assume the same potential as the rotor segments, are electrically well enclosed and therefore cannot build up an electrical field with respect to the environment.

The cover disk is preferably constructed as a sandwich of cover disk segments, an insulation disk and a shielding disk. Together with the insulation and the shielding disk, the cover disk segments form a defined capacitor. As the shielding disk is electrically connected to the rotor base via screws, the rotor segments including the blades are also shielded from the environment. As a result, the potential of the blades is only influenced by any additional capacitance of a cable to be processed in the event of blade-conductor contact, which can be detected by the contact detection device. Furthermore, such a cover disk can be used to determine which rotor segments are electrically connected to the blade-conductor contact detection device. If the cover disk is mounted so that the insulation between the cover disk segments is directly above the insulation between the rotor segments, only the first rotor segment is connected to the contact detection device; the others are potential-free. However, if the cover disk is mounted in such a way that the first rotor segment is electrically connected to other rotor segments via the cover disk, these are also connected to the contact detection device.

In another preferred embodiment of the device according to the invention, the rotary tool holding apparatus is provided with at least one bridging bar receiving region which is formed in two adjacent rotor segments arranged relative to one another, the at least one bridging bar receiving region preferably comprising at least one, preferably a plurality of, particularly preferably two fastening means receiving regions for preferably reversibly receiving fastening means for fastening bridging bars to be received in the bridging bar receiving regions, preferably a plurality of, particularly preferably two fastening means receiving regions for the preferably reversible receiving of fastening means for the fastening of bridging bars to be received in the bridging bar receiving regions. In this way, it is possible to convert the proposed rotary tool holding apparatus in a simple manner so that a desired electrical connection can be realized (reversibly) between two rotor segments that are otherwise electrically insulated from each other. It should namely be noted that there are also application situations and/or tools to be used in which an electrical connection between the rotor segments—and thus possibly also an electrical connection between the (electrically conductive) tools accommodated therein—is advantageous. In this context, for example, checking whether individual strands of a cable to be stripped protrude outwards comes to mind. The universal applicability of the rotary tool holding apparatus can be significantly increased by the proposed design.

In still another preferred embodiment of the device according to the invention, the rotary tool holding apparatus is designed in such a way that, in the presence of a plurality of bridging bar receiving regions, the bridging bar receiving regions are at least partially designed differently, in particular differently with respect to their contour. By means of a different design of the bridging bar receiving regions, it is possible in particular that individual receiving regions cannot be confused with each other. Moreover, it is possible that a bridging bar corresponding to the different contours of the bridging bar receiving regions is provided. These can be uniquely designed, in particular with regard to their contour, in such a way that only a certain type of bridging bar can be inserted into a certain type of bridging bar receiving region. Irrespective of whether the bridging bar receiving regions are designed differently or not, it is advantageous if the bridging bar receiving regions are designed to be reversible. In particular, this means that it is possible for bridging bars, in particular bridging bars in the form of flat elements, which can be inserted into the corresponding bridging bar receiving region, to be simply turned over, and can also be inserted into the corresponding bridging bar receiving region in the turned-over position. In particular, this makes it possible to use bridging bars that have an electrical contacting element on one side, but an insulating surface area on the other. It is then possible for the adjacent rotor segments to be either electrically contacted with each other or electrically insulated from each other by simply turning the relevant bridging bar. An especially simple and quick adaptability of the rotary tool holding apparatus for different applications can thus be realized. The electrical implementation can take place in particular by means of direct contact of an electrically conductive surface area of the bridging bar with corresponding parts of the bridging bar receiving regions or the tool holding apparatus/rotary segments, but can also be realized indirectly, for example by means of a screw serving as fastening means, which is screwed into a screw thread to fasten the bridging bar. In particular, electrical contact can be made between the screw head and an electrically conductive surface area of the bridging bar.

It is pointed out that one, some, the majority or (approximately) all of the bridging bar receiving regions/bridging bars can also be realized in the form of controllable switching elements, in particular controllable electronic switching elements. In this way, a particularly quick and easy adjustment of the rotary tool holding apparatus (a controlled “retooling”) is possible in a particularly simple and quick manner, if necessary also during operation of the device. As a result, an electrical connection between two rotor segments could be established or interrupted by switching a corresponding controllable switching element. Similarly, an additional capacitance could be added to or removed from the rotor base by switching a corresponding controllable switching element of the relevant rotor segment.

Additionally, or alternatively, it is proposed that in the rotary tool holding apparatus, the fastening means receiving regions for receiving fastening means for fastening bridging bars to be received in the bridging bar receiving regions are electrically insulated from the rotor base. The fastening means could be screws, for example. On the one hand, it is possible to use screws made of an electrically insulating material (e.g. plastic screws). However, it makes sense if the fastening means receiving regions are electrically insulated, for example with an electrically insulating screw thread insert. In this case, commercially available screws can be used to fasten the bridging bars in the respective tool holding areas. This effectively prevents a person carrying out a conversion of the rotary tool holding apparatus from realizing a misconfiguration of the same by using commercially available screws, since he has no “special screws” available and is not aware of the problems of this procedure. In this context, it should be noted that an electrically conductive configuration makes sense for some fastening means receiving regions/screw threads, as such electrical conductivity is described/required elsewhere in the context of this text. For the sake of completeness only, it is pointed out that an additional possibility of incorrect contact could occur here, as different types of screws may have to be used, which could be mistakenly interchanged.

In another preferred embodiment of the device according to the invention, the rotary tool holding apparatus has at least one pocket region provided in a rotor segment for receiving a capacitive element, the pocket region preferably being formed in exactly one of the rotor segments, in particular in the rotor segment which is electrically connected to the device for detecting contact from an electrical conductor. With such an embodiment, it is possible to compensate the rotor segment rotor base capacitances of the other rotor segments not connected to the first rotor segment by a capacitance as an electronic component, so that the natural frequency of the LC resonant circuit consisting mainly of the coupling coil and the rotor segment rotor base capacitances does not shift inadmissibly, which could, for example, lead to excessive damping of the resonant circuit. The additional capacitance can, for example, be easily connected electrically to the first rotor segment via a short screw and to the rotor base via a longer screw through a hole in the first rotor segment. The longer screw does not touch the first rotor segment and is electrically insulated from it. This makes the proposed rotary tool holding apparatus particularly universally usable, as it can be easily (preferably reversibly) converted for this purpose. It is obvious that such extensive universal usability of the rotary tool holding apparatus is advantageous.

Similar to what was previously mentioned in connection with bridging bar receiving regions, controllable switching elements, in particular controllable electronic switching elements, can also be used here for one, some, the majority or (nearly) all pocket areas. This may involve electrically connecting a capacitance between the first rotor segment and the rotor base and/or changing the size of a capacitance between the first rotor segment and the rotor base. The advantages with regard to a particularly quick and easy adjustment of the rotary tool holding apparatus (a controlled “retooling”), possibly also during operation of the device, are obvious.

In a further preferred embodiment of the device according to the invention, the at least one pocket region has at least one, preferably a plurality, particularly preferably three fastening means receiving regions for receiving fastening means for fastening a capacitive element in the pocket region, wherein preferably a first of the fastening means receiving regions is electrically connected to the respective rotor segment and electrically insulated from the rotor base, a second of the fastening means-receiving regions is electrically connected to the rotor base and electrically insulated from the relevant rotor segment, and a possible third of the fastening means receiving regions is connected to the rotor base and electrically insulated from the relevant rotor segment (6) or is insulated from the rotor base (2) and electrically connected to the relevant rotor segment (6). The third fastening means receiving region, which is not connected to any of the capacitance connections, is only used to supply the fastening means that is not required if the capacitance is not to be contacted. Of course, another type of configuration is also possible, such as direct contact between a conductive surface of the capacitive element and corresponding areas of the pocket area (possibly including fastening means receiving regions). With regard to the design of the fastening means receiving regions, for example in the form of screw threads, which may be designed with or without electrical insulation, what has been said in connection with fastening means receiving regions can apply to bridging bar receiving regions. The proposed particularly preferred design with three fastening means receiving regions makes it possible in particular to realize a suitable electrical contacting of a suitable capacitive element which is to be received by the pocket area. In addition, a particularly advantageous contouring is thereby realized, so that a particularly clear and intuitively recognizable difference to the bridging bar receiving regions or respectively the bridging bars can be achieved. Once again, it is preferable if the pocket area or respectively the capacitive elements are designed in particular like a flat element and/or are designed to be reversible, in such a way that the capacitive element still fits into the pocket area by turning the capacitive element around accordingly, and a capacitance can be looped into the circuit or removed from it by appropriately selecting the position/configuration of the capacitive element. If necessary, however, a different type of electrical contacting can be realized.

In a further preferred embodiment of the device according to the invention, at least one of the tool holding areas, preferably a plurality of tool holding areas, particularly preferably all of the tool holding areas, has an adjustment means for adjusting the position of a tool arranged in the relevant tool holding area. In this case, a movability of the relevant tools is particularly easy to realize. As already mentioned, the adjustment means can be designed to be virtually as desired, in particular electrically, mechanically, pneumatically or hydraulically adjustable, possibly also in combination with one another. Adjusting the tools is useful, for example, to move cutting blades inwards (to name just one example) in order to be able to cut into an outer insulating sheath of a cable to be stripped.

Although the number of tool holding areas can be varied, it generally proves to be advantageous if a multiplicity of tool holding areas is provided, which preferably extend over a substantially similar angular division. In particular, three or six tool holding areas should be considered. With such an embodiment, a particularly good symmetrical application of force can be realized in a cable to be stripped, so that any bending effects of the cable can be largely prevented. Especially with three or six tool holding areas, the tool holding apparatus is still relatively simple and inexpensive to realize. In particular, three rotor segments should be considered in this context, of which each rotor segment has two tool holding areas (i.e. six tool holding areas are present). For the sake of completeness only, it is pointed out that during operation of the rotary tool holding apparatus, not all tool holding areas must necessarily be provided (equipped) with a tool. Rather, it may prove to be advantageous if, for example, only some of the tool holding areas are equipped with tools, at least for certain applications, such as when only every second of the tool holding areas is equipped with a tool.

In another preferred embodiment of the device according to the invention, a tool is arranged in at least one of the tool holding areas, in particular a cutting tool, a cutting blade tool, a blunt blade tool, a perforation tool, a hook tool, a cutting hook tool, a blunt hook tool, a flanging tool or an insulation slitting tool. The tool(s) in question may preferably have an electrically conductive material or be formed from such a material (whereby the materials already mentioned, such as in particular steel and/or tool steel, are to be considered). When using such tools, typical stripping tasks or measuring tasks in connection with stripping tasks can be realized particularly advantageously. It can prove to be advantageous if different tools are combined with each other. In particular, special pairings of different tools can prove to be especially advantageous. Here, for example, a pairing of a cutting blade tool with several blunt blade tools or a pairing of cutting blade tools and hook blade tools should be considered. In the case of hook blade tools, it is also possible for the hook area to be narrower or wider than the bearing area of the hook blade tool, for example to determine the width of the sheath rings that are to be removed from a cable. Other combinations are of course also conceivable. The tools in question are at least partially known per se in the prior art.

In another preferred embodiment of the device according to the invention, a tool is arranged in a multiplicity of the tool holding areas, in a defined fraction of the tool holding areas, or in all tool holding areas, with the tools preferably being identical or functionally complementary to one another. The defined fraction can be, for example, half, a third or a quarter of the existing tool holding apparatuses. The specific design usually depends on the specific stripping or measuring task. For example, in some stripping tasks it is advantageous to use three identical blade tools, whereas in stripping tasks for special cable types (e.g. coaxial cables with shield and foil) it is advantageous to use a cutting blade tool and otherwise blunt blade tools. In this context, for example, cutting blade tools and blunt blade tools or cutting hook blade tools and blunt hook blade tools are to be regarded as functionally complementary to one another. In particular, this combination results in an advantageously uniform and symmetrical application of force to the cable to be stripped, so that it is not bent away during the stripping process. The use of a single cutting edge (and otherwise only blunt cutting tools) is again advantageous in that unwanted damage to electrically conductive parts of the cable can be avoided in the case of a cable to be stripped with a non-rotationally symmetrical structure (for example a coaxial cable with shielding foil).

In a further preferred embodiment of the device according to the invention, a bridging bar is arranged in at least one of the bridging bar regions, wherein the bridging bar is preferably formed asymmetrically (in the case of a flat element, in particular with respect to its flat surface sides), in that it has a first, electrically connecting insertion position, in which it electrically connects the relevant rotor segments lying adjacent to one another, and a second, electrically insulating insertion position, in which it does not electrically connect the respective rotor segments lying adjacent to one another. The relevant advantages and properties of such a design, in particular also with regard to a suitable design of the bridging bars, have already been explained in the foregoing, which is why, for reasons of brevity, no further details are provided here.

In a further preferred embodiment of the device according to the invention, a capacitive element is arranged in at least one of the pocket areas, the capacitive element preferably being designed asymmetrically, in that it has a first insertion position providing a capacitance, in which the capacitance of the capacitive element is connected between two of its fastening areas, and a second insertion position not providing any capacitance, in which the capacitance of the capacitive element is not connected between the two fastening areas in question. The advantageous embodiment described has also already been described in connection with the pocket areas, at least in analogous form, which is why, for reasons of simplicity, no further explanations are given here, and reference is made to the above description. In the present case of a capacitive element in particular (but not only here), an “insertion position” can also be understood to mean, additionally or alternatively, a suitable configuration with regard to the number and arrangement of the fastening means/screws used. If “no capacitance is provided”, this can mean in particular that there is no electrical connection via the capacitive element between the rotor base and the first rotor segment via the fastening means in the position/configuration in question. It is also advantageous if a certain set of capacitive elements with different capacitances (in particular capacitors of different sizes) is available. In such a case, a capacitance of a suitable size for the specific task can be selected from the set and inserted into the relevant pocket area or connected by the fastening means or by an analog switch. Depending on the specific task, capacitors of the same size can be inserted into the different pocket areas, or capacitors of different sizes can be inserted into different pocket areas.

In yet another preferred embodiment of the device according to the invention, the device for detecting contact from an electrical conductor comprises at least one coupling coil device, preferably comprising a rotor coil and a stator coil, for in-coupling and out-coupling high-frequency electrical signals, which is preferably arranged radially symmetrically to the rotary tool holding apparatus. In this way, measurements can be carried out advantageously and, in particular, measurement errors due to any poor electrical contacting, for example via sliding contacts, which were often used in lathe-type machine tools, can be avoided. Not only can measured values and control signals be coupled in and out, but it is also possible to supply power to any components on, to or in the rotary tool holding apparatus via the coupling coil device. If necessary, control signals for controlling the controllable switching elements—if present—can also be introduced via the coupling coil device. Of course, the coupling coil device can also transmit data in addition to supplying a rotor-side electronic system. It is therefore conceivable that the electronics for contact detection are alternatively fitted on the rotor side and the data for contact detection is transmitted via the coupling coil device. This can be done, for example, via a modulated power supply to the rotor-side electronics. However, it is also conceivable that the energy and data transmission are carried out separately via two different coupling coil devices, preferably with different frequencies. The data could thereby be transmitted in a second coupling coil device, e.g. by frequency or amplitude modulation. Another possibility would be to transmit the data optically. In particular, it is proposed that the coupling coil device is arranged in a projection area of the rotary tool holding apparatus. In this way, the signals can be coupled in and out in a particularly advantageous way. In particular, this proposal accommodates the usual designs of rotary tool holding apparatuses (including other system components). Furthermore, with the proposed design, any signal interference can be avoided due to the environmental electromagnetic shielding effect. It is also proposed that the coupling coil device is connected to an overvoltage protection device. This can effectively prevent any damage. In principle, any devices available in the state of the art can be considered, such as, for example, two diodes (or an anti-parallel circuit consisting of two or more diodes connected in series). It is also useful if the rotary tool holding apparatus has at least one capacitance receiving region for receiving a capacitance or has a capacitance that can be used in particular for frequency adjustment of a resonant circuit. It is also possible for a rotor coil end to be electrically connected to an electronic switching element that electrically connects a capacitance between the rotor coil ends. In this way, the rotary tool holding apparatus can be suitably adjusted and optimized to the current measuring task “from the outside”, so to speak, by means of a suitable control signal, even during operation.

In yet another preferred embodiment of the device according to the invention, at least one controllable switching element is provided, in particular at least one controllable electronic switching element, which in particular establishes or interrupts a controllable, reversible electrical connection between two rotor segments arranged adjacent to one another and/or which in particular connects or removes a capacitance in a circuit, in particular introduces or removes a capacitance between the first rotor segment and the rotor base. Such a design can, in particular, represent a kind of “electrically controllable analog” to the previously described bridging bar receiving regions/bridging bars or to the previously described pocket areas/capacitive elements. The advantages and properties already mentioned can also apply here, at least by analogy. It is particularly advantageous that a particularly simple switchover is possible, which can also take place during operation of the rotary tool holding apparatus or the system to which the rotary tool holding apparatus is attached.

Furthermore, a cable stripping machine is proposed which has a rotary tool holding apparatus according to the structure described above. Such a stripping machine can also exhibit the advantages and properties described above at least in an analogous manner. In addition, the stripping machine as previously described can be further developed in at least an analogous manner, whereby the advantages and properties also already described can be achieved at least in an analogous manner.

In a second aspect of the present invention, a method for removing a shielding foil with a rotary tool holding apparatus according to the present invention comprising the following steps is proposed:
a. Equipping the tool holding areas with tools, wherein the number of tools is selected such that no electrical contact is created between the rotor segments, wherein only one of the tools has a sharp edge and wherein the tool with the sharp edge is positioned in the at least one tool holding area of the rotor segment which is electrically connected to the device for detecting contact from an electrical conductor.
b. Creating a predetermined breaking point in the shielding foil by pressing in the tools until the tool with the sharp edge has reached a maximum predetermined depth or until contact of an electrical conductor with the tool with the sharp edge is detected.
c. Repeating step b multiple times after the tools have been retracted and rotated by an adjustment angle (a) around the electrical cable.
d. Tearing through the shielding foil at the predetermined breaking point;
and
e. Pulling off the shielding foil.

The method according to the invention makes it possible to create a predetermined breaking point in a shielding foil without damaging the underlying shielding braid in an impermissible way. The foil wrapping of a cable is not perfectly round. Therefore, if all blades were connected to the device for detecting contact, as in the devices known from the prior art, the foil would most likely not be perforated completely over the entire circumference, although contact between a blade and the shielding braid would be detected again after each adjustment angle, because it would not be clear which blade had caused the contact, detected it and perforated the foil. Advantageously, the cable sheath can be cut to a fraction of its thickness by rotary cutting before step b. Advantageously, the cable sheath can also be partially or completely removed after the rotary incision.

In a first embodiment of the method according to the invention, the bridging bars located in the bridging bar regions are brought into their respective insertion position, the bridging bars are brought into the bridging bar regions in their respective insertion position or the bridging bars located in the bridging bar regions are removed from the bridging bar regions and/or the respective controllable switching elements are brought into their respective correct switching position. Alternatively, or additionally, any existing controllable switching elements in question can also be brought into their correct switching position. This also applies in the following, in particular when we are talking about bridging bars to be accommodated in bridging bar areas and/or capacitive elements to be accommodated in pocket areas. In the present case, the “relevant controllable switching elements” are controllable switching elements that can establish or interrupt a reversible electrical connection between two rotor segments in a controlled and reversible manner. The method is particularly suitable for use with a rotary tool holding apparatus of the design described above. It is particularly advantageous if the bridging bars remain permanently in their corresponding bridging bar areas and are each brought into their respective insertion position, for example by “turning them over”. In this way, they cannot be lost during the working phases of the relevant stripping machine between the refitting phases, which is of course an advantage. It is again pointed out that an “insertion position”, in particular in the present context (but not only here), may additionally or alternatively also be understood to mean the number and/or arrangement of the fastening means used/to be used. In principle, however, it is also possible for the bridging bars to be removed during a transfer phase/conversion phase and stored elsewhere temporarily, or for bridging bars stored elsewhere temporarily to be inserted into the relevant bridging bar areas. The possibility of removing/adding bridging bars (possibly also capacitive elements) in combination with intermediate storage of the same elsewhere should also explicitly apply to the process embodiments described below, even if it is not explicitly mentioned there.

It is further proposed that in the process, the capacitive elements located in the pocket areas are brought into their respective insertion position, the capacitive elements are brought into the pocket areas in their respective insertion position, and/or the controllable switching elements are brought into their respective correct switching position. Analogous to what has been said with regard to the bridging bars, it makes sense if the capacitive elements remain permanently in the relevant pocket areas and are brought into their respective insertion position during the transfer or changeover phase, if necessary, by turning them over (or possibly reconfiguring the fastening devices). However, it is also possible that also or only the capacitive elements are temporarily stored elsewhere and removed or added. In particular, it is also possible for a set of capacitive elements with different capacities to be kept ready so that the size of the capacitance present in the respective pocket area can be changed and adapted to the respective specific task during the work step in which the capacitive elements are placed in their respective insertion position in the pocket areas or removed from the respective pocket areas. In particular, resonant frequencies can be adjusted in this way. In the present case, the “relevant controllable switching elements” are controllable switching elements that can introduce a capacitance into a circuit in a controlled and reversible manner or remove it from the circuit.

In particular, it is proposed that the capacitive elements located in the pocket areas are brought into their first insertion position providing a capacitance and/or the controllable switching elements are brought into a switching position determining the frequency for the coupling coil device. It is also possible that the capacitive elements located in the pocket areas are brought into their first insertion position providing a capacitance and/or the controllable switching elements are brought into a switching position in which the relevant capacitance is looped into the circuit, and high-frequency measurement methods (as described, for example, in EP 2 976 818 B1) are used.

### BRIEF DESCRIPTION OF THE DRAWINGS

Further details of the invention and in particular exemplary embodiments of the proposed device and of the proposed method will be explained in the following with reference to the attached drawings. Shown are:

FIG. 1: a perspective view of a rotary cutting head with electrically connected cutting blade tools known from the prior art;

FIG. 2: a perspective view of a rotary cutting head with electrically interconnected rotor segments and cutting blade tools inserted therein;

FIG. 3: a first embodiment example for a bridging bar inserted into a bridging bar receiving region in a first configuration in plan view;

FIG. 3a: a sectional view of a first embodiment of a bridging bar inserted into a bridging bar receiving region in a first configuration;

FIG. 4: a first embodiment example for a bridging bar inserted into a bridging bar receiving region in a second configuration in plan view;

FIG. 4a: a sectional view of a first embodiment of a bridging bar inserted into a bridging bar receiving region in a second configuration;

FIG. 5: a second embodiment example for a bridging bar inserted into a bridging bar receiving region in a first configuration in plan view;

FIG. 5a: a sectional view of a second embodiment for a bridging bar inserted into a bridging bar receiving region in a first configuration;

FIG. 6: a second embodiment example for a bridging bar inserted into a bridging bar receiving region in a second configuration in plan view;

FIG. 6a: a sectional view of a second embodiment of a bridging bar inserted into a bridging bar receiving region in a second configuration;

FIG. 7: a top view of an embodiment example for a capacitor bar inserted in a capacitor bar receiving region in a first configuration;

FIG. 7a: a sectional view of an embodiment example for a capacitor bar inserted into a capacitor bar receiving region in a first configuration;

FIG. 8: a top view of an embodiment example of a capacitor bar inserted into a capacitor bar receiving region in a second configuration;

FIG. 8a: a sectional view of an embodiment example for a capacitor bar inserted into a capacitor bar receiving region in a second configuration;

FIG. 9: a perspective view of a rotary cutting head with hook blade tools;

FIG. 10: a block diagram for an embodiment example of a method for removing a shielding foil;

FIG. 11: a rotary cutting head with a coupling coil device arranged in the outer circumferential area in a plan view from the front;

FIG. 12a: a first partial section of the coupling coil area of the rotary cutting head shown in FIG. 11;

FIG. 12b: a second partial section of the coupling coil area of the rotary cutting head shown in FIG. 11;

FIG. 13: a partial view of the coupling coil area of the rotary cutting head shown in FIGS. 11, 12a and 12b;

FIG. 14: a perspective view of the rotary cutting head as shown in FIG. 11 with a different tool configuration compared with FIG. 11;

FIG. 15: a first embodiment of a cover disk in a perspective view;

FIG. 16: a perspective view of another possible embodiment example of a rotary cutting head with a radially positioned internal insulation ring;

FIG. 17: a second embodiment of a cover disk in a perspective view;

FIG. 18: a detailed view of the embodiment shown in FIG. 16, in which the insulation ring has been omitted;

FIG. 19: a perspective view of the segmented rotor end face and the rotor base with a partial section of the rotor end face to make the glue pockets visible;

FIG. 20: a perspective view of the segmented rotor end face in a further embodiment, in which the tool holding areas are designed such that the tools have a radially symmetrical pivot range, for example for blades with a sharp and a blunt edge;

FIG. 21: a perspective view of the segmented rotor end face according to FIG. 20 in which the tools are designed with an elongated hole or fork guide for the pivot pins and a round hole for the positioning pins;

FIG. 22: a perspective view of the segmented rotor end face in a further embodiment, in which the segments are designed in such a way that the blades can have a first sharp edge and a second edge in the form of a hook tool.

FIG. 23: a perspective view of the segmented rotor end face in a further embodiment, in which the reference circle diameter of the adjusting pins is larger than that of the pivot pins, and the pivot pins engage in round holes and the adjusting pins engage in elongated holes or fork guides of the blades;

FIG. 24: shows a possible application example of how an electrically conductive shielding foil of a multi-core cable can be perforated with the aid of a segmented rotor end face;

FIG. 25: illustrates a first method of measuring the eccentricity between a round bar and the rotary cutting head; and

FIG. 26: illustrates another method of measuring the eccentricity between a round bar and the rotary cutting head.

### PREFERRED EMBODIMENTS OF THE INVENTION

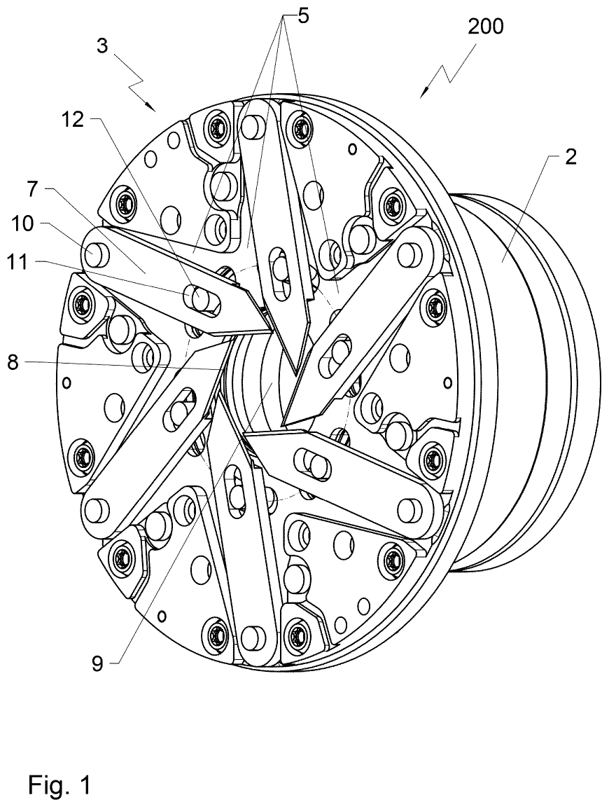

FIG. 1 shows a rotary cutting head 200 in a design for blade-conductor contact detection. In principle, such rotary cutting heads 200 without insulation between the tool holding areas are known in the prior art. The basic structure of such a cutting head is known purely as an example from WO 2020/119916 A1.

The cutting head 200 shown here has a rotor base area 2, which can be set in a rotational movement by a drive not shown here.

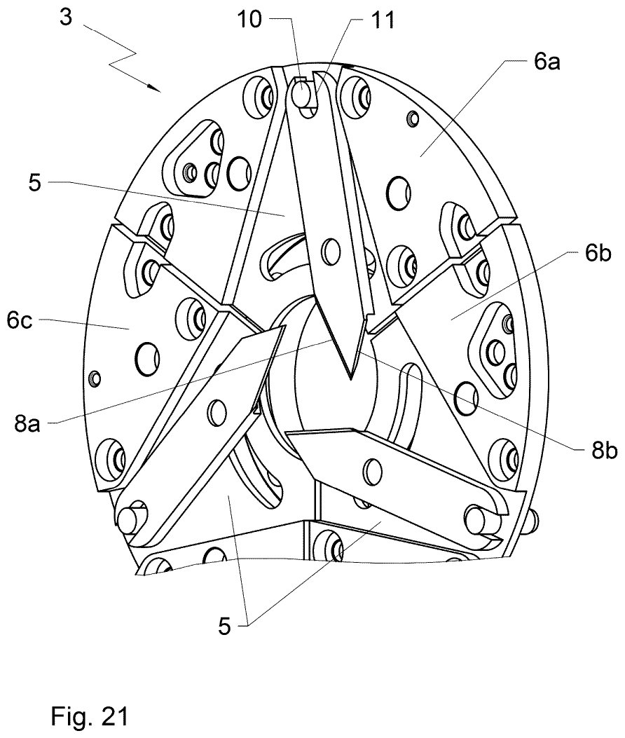

Further forward in the axial direction, a rotor end face 3 is attached to the rotor base 2, which has a plurality—in this case six—of tool holding areas 5. A tool 7 is pivotably mounted in each tool holding area 5, in this case a cutting blade 7 with a sharp edge 8 at the front of the blade. Each cutting blade 7 is rotatably mounted on a pivot pin 10 in an outer region opposite the radial center 9. In a front area of the cutting blades 7 adjacent to the radial center 9, these are each provided with an elongated hole 11 in which an adjusting pin 12 engages. The adjusting pin 12 can be pivoted each time in a circumferential direction so that the circumferential area formed by the blade edges 8 can be enlarged or reduced. It is also possible to provide the cutting blades 7 with an elongated hole or fork guide in the area of the pivot pin 10 as shown in FIG. 21 and to form the cutting blades 7 with a round hole in the area of the adjusting pin 12. It is furthermore possible to swap the radii of the pivot pins and the adjusting pins as shown in FIG. 23. An advantage of this arrangement is that the banana tracks and the elongated holes or fork guides for the adjusting pins are moved to the outer area of the rotary cutting head, which is less susceptible to interference caused by production waste such as stranded wires, insulation or other cable parts.

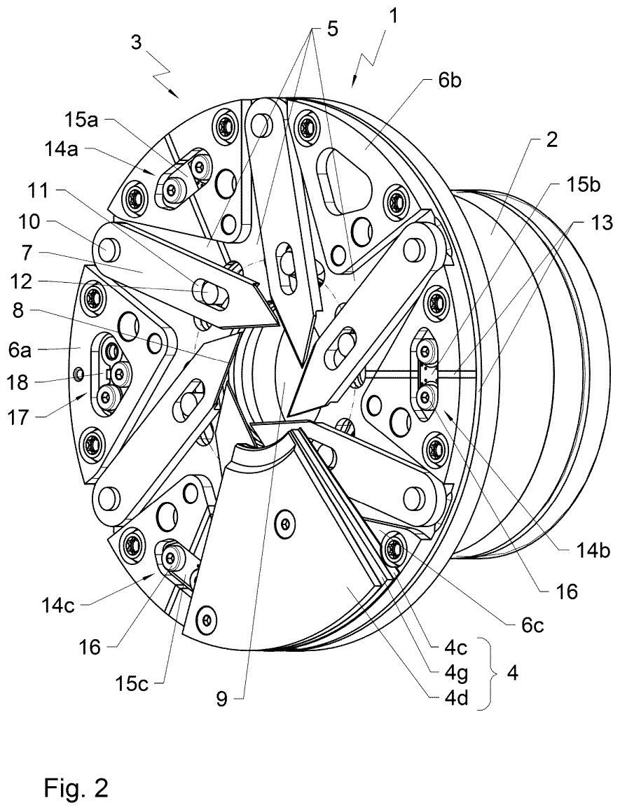

The rotary cutting head 200 is closed at the front by a cover disk, whereby the cover disk is not shown in this FIG. 1 for illustrative reasons (a part of the cover disk is shown in FIG. 2).

In rotary cable processing machines, it is advantageous to provide a device for detecting contact between a blade and the cable conductor, a so-called blade-conductor contact detection device. When processing many cables, it is important that the blades do not cut into the conductor (in the following, conductor can also mean a shielding foil or a shielding braid). In a rotary cutting head, the rotor segments 6 are therefore electrically insulated from the rotor and monitored with an electrical signal for blade-conductor contact detection.

The blade-conductor contact detection system can not only detect and continuously store a contact during the rotary incision, but also during other work steps, whereby the relevant process variables (such as positions, speeds, accelerations and forces [e.g. those of the cable gripper, the centering unit, the cutting head]) can always be stored, processed and recorded at the time of contact for regulation, control, quality control, statistics or further analyses.

The blade-conductor contact detection can also be used to determine the position of the cable gripper at which the cable end has reached the blade level when it is inserted into the cutting head. The blades are closed for this purpose and the cable insertion speed is greatly reduced before the blade level. When the cable comes into contact with the blade conductor, the cable insertion is stopped, the gripper position is saved, and the blades are opened. Starting from this position, the cable can be inserted into the cutting head at the desired processing length.

The blade-conductor contact detection can also be used to check that no strands are protruding axially beyond the cable end after a stripping process, for example. To do this, the cable end is brought just before the blade level and the blades are closed.

Blade-conductor contact detection can also be used to check that all strands of a coaxial cable have been cut cleanly and moved together with the sheath after a cut of the sheath and shield with subsequent pull-off or partial pull-off. For this purpose, the pull-off movement can be stopped after a short pull-off distance, for example, whereupon the cable is moved back about half the pull-off distance relative to the blades so that the blades do not touch either the stripped shield section or the cable shield. In this position, the blades can be rotated with the opening diameter corresponding to the outer diameter of the dielectric. If not all strands have been cut cleanly and moved together with the sheath, a blade-conductor contact detection is detected.

Blade-conductor contact detection can also be used to check that no strands protrude radially beyond a certain radius after a shield processing operation, for example. The blade opening is set to the diameter to be tested and the cable area to be tested is guided through the cutting plane while the cutting head rotates.

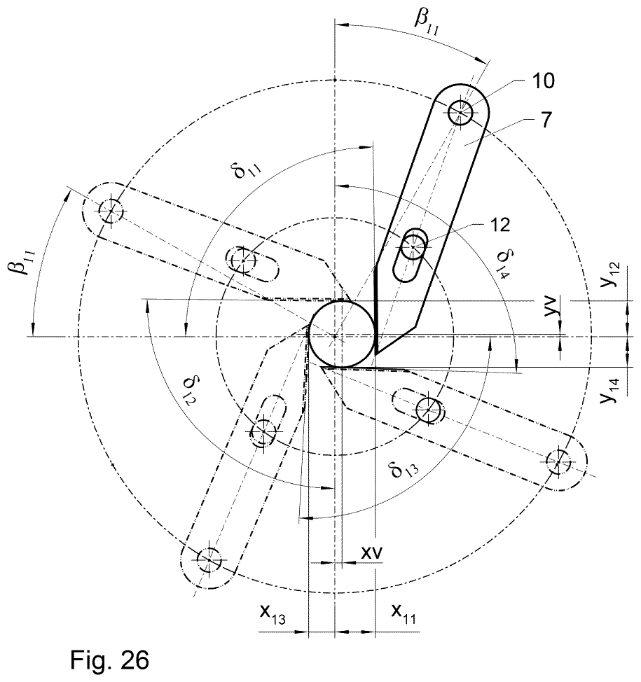

According to FIG. 25, blade-conductor contact detection can also be used to measure the eccentricity between a round bar and the rotary cutting head, whereby the round bar is inserted and held in the rotary cutting head by the cable holder instead of a cable. The rotary cutting head is preferably fitted with only a sharp or blunt blade for this measurement. With the cutting head not rotating, the one blade is slowly advanced until a first contact between the blade and the round bar is detected, with the associated first adjusting pin angle φ1 preferably being stored at the time of the first contact. The blade is retracted and the rotary cutting head is rotated, preferably by 120°, whereupon the blade is advanced again until a second contact is detected, whereby the associated second adjusting pin angle φ₂ is stored. The measurement is repeated and a third adjusting pin angle φ₃ is stored. It is known from the international patent application WO 2020/119916 A1 that the cutting diameter can be calculated via a deflection roller displacement e, the adjustment pin angle φ, the blade pivot angle λ.

The straight line ms, which represents the cutting edge of the blade 7, is also known via the blade swivel angle) and the blade geometry. The three stored setting ring angles φ₁, φ₂ and φ₃ can be used to calculate the three straight line equations ms1, ms2 and ms3, which form a triangle whose inscribed circle represents the round bar with its eccentricity values xv and yv in relation to the rotary cutting head. These eccentricity values can be used to correct the position of the cable holder such that the round bar and therefore also the cables are held exactly centrally in the rotary cutting head. The exact derivation of the geometric relationships is omitted here. This adjustment process does not require any additional devices, as it can be carried out automatically by the process control system. Preferably, the round rod is made of a highly conductive, rather soft metal, such as copper, whereby contact detection is ensured and the blade edge is protected. In order to record the blade position at the time of blade-round bar contacts, another value indicating the blade position can be stored instead of the adjusting pin angle, such as, for example, the deflection roller displacement e or the blade pivot angle 2.

FIG. 26 shows another method of measuring the eccentricity between a round bar and the rotary cutting head. However, the method is overdetermined and inaccurate for larger eccentricity values, so it may need to be repeated after an initial adjustment of the cable holder. At the start of the eccentricity measurement, the rotary cutting head is rotated so that the pivot pin of the blade is at an angle (β₁₁) that is selected so that the cutting edge of the blade would be vertical when the blade touches the round bar if the round bar were held centrally. If the round bar is held off-center, the cutting edge is not quite vertical (and δ₁₁ not quite) 90°. In this cutting head position, one cutter is slowly fed with the cutting head not rotating until a first contact between the cutter and the round bar is detected, whereby the associated first assumed radius of the round bar (x11) is stored at the time of the first contact. The blade is retracted and the rotary cutting head is rotated by 90°, whereupon the blade is retracted again until a second contact is detected, whereby the associated second assumed radius of the round bar (y12) is stored. The measurement is repeated, and a third contact is detected, whereby the associated third supposed radius of the round bar (x13) is stored. The measurement is carried out a fourth and final time, whereby the associated fourth assumed radius of the round bar (x14) is stored. The horizontal (component of the) eccentricity (of the offset) (xv) is half the difference between the first and third supposed radius of the round bar (xv=(x11−x13)/2) and the vertical (component of the) eccentricity (of the offset) (yv) is half the difference between the second and fourth assumed radius of the round bar (yv=(x12−x14)/2). With these eccentricity values, the position of the cable holder can be corrected such that the round bar and thus also the cables to be processed are held exactly centrically in the rotary cutting head. The exact derivation of the geometric relationships is dispensed with here.

If a blade-to-sheath contact is to be detected on a coaxial cable, either for teaching the cutting diameter or for controlling or monitoring the cable processing, it must be prevented that the blades still touch the shield. Either the coaxial cable is stripped in stages, or the sheath and shield are first partially stripped, whereupon the cable is moved back about half the stripping distance relative to the blades if the partially stripped shield piece is large enough to trigger a blade-conductor contact.

A rotary ring cut in a cable often cannot be made to the required depth without damaging the conductor(s), as the insulation thickness often varies along the cable circumference. To solve this problem, the cutting head can be equipped with one sharp blade and two blunt blades. After a rotary cut to just before the conductor, the rotation is stopped, and the blades are moved closer until a blade-conductor contact is detected. The blades are then opened again slightly, the cutting head is rotated slightly, and the blades are advanced again. This is repeated until the remaining insulation thickness has been cut along the entire cable circumference. In order to ensure that the blade-conductor contact signal can only be triggered by the sharp blade, thus ensuring that the insulator is continuously cut through to the conductor over the entire circumference, the blunt blades can be made at least partially of ceramic. Since ceramic blades are very complex and expensive, they should advantageously be able to be replaced by blunt blades made of metal. However, these blades must not be able to trigger a contact signal in the event of blade-conductor contact, which according to the present invention can be achieved with segmented tool holding areas.

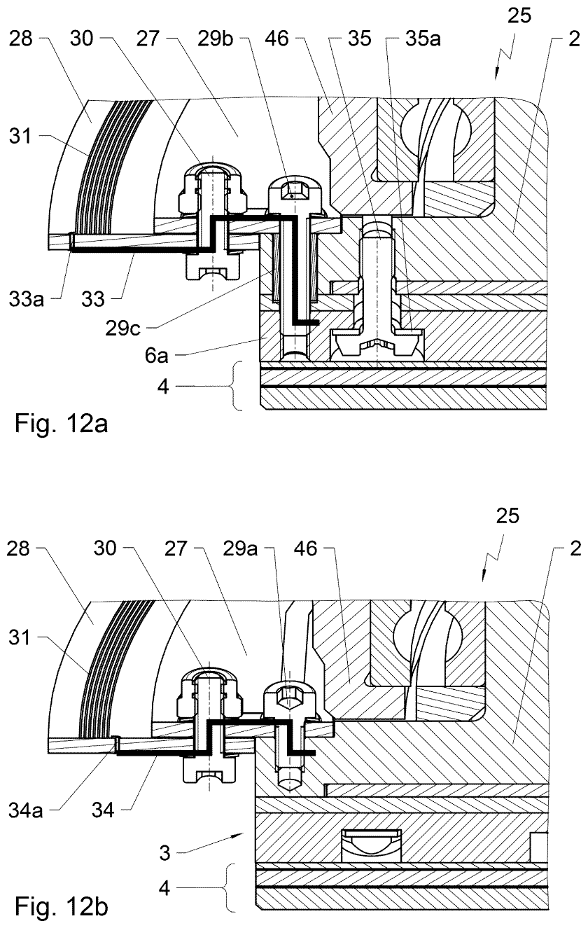

As can be seen from FIG. 2, in a first preferred embodiment of a rotary tool holding apparatus according to the present invention, a total of six tool holding areas 5 are each grouped into pairs of two and subdivided into a total of three rotor segments 6. A device known per se for detecting contact with an electrical conductor is provided and electrically connected to at least one first rotor segment 6a (here via a screw in the threaded hole on the left of the capacitor bar receiving region 17, as also shown in FIG. 12a with screw 29b).

The individual rotor segments 6, three in total, are each electrically insulated from one another and from the rotor base 2 by an insulating layer 13. The metallic surface 4d of the cover disk 4 is also electrically insulated from the rotor segments 6 and the tool holding areas 5 by means of an insulating layer 4g.

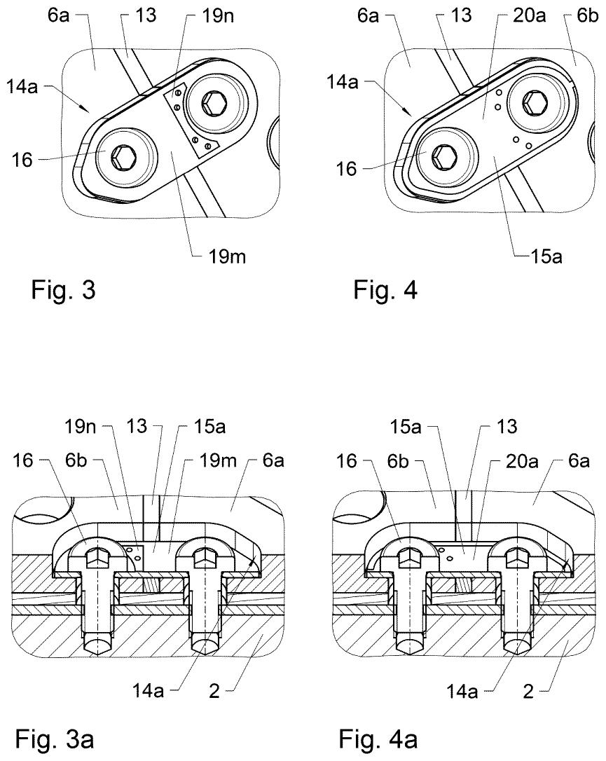

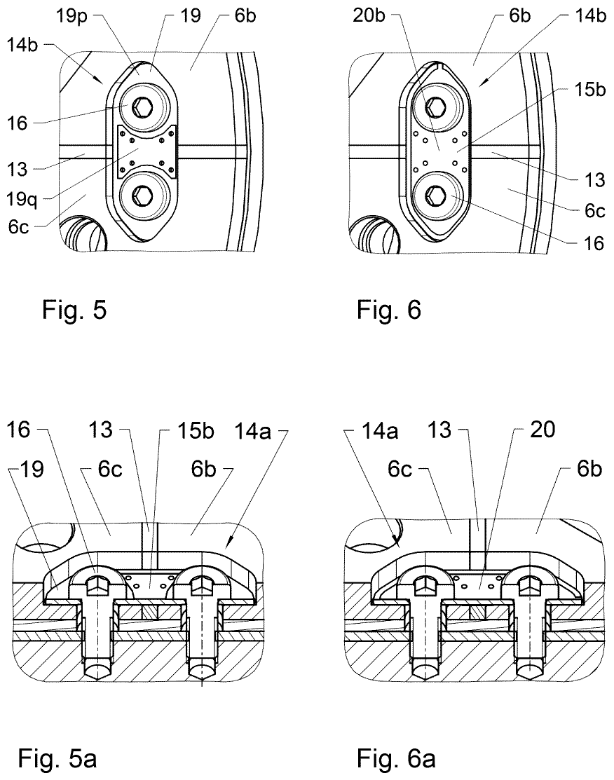

In the embodiment example of the rotary cutting head 1 shown in FIG. 2, a bridging bar receiving region 14 is also provided in each of the areas in which two rotor segments 6 are located adjacent to one another, with one half of the bridging bar receiving regions 14 being formed in each of the two rotor segments 6 arranged adjacent to one another. A bridging bar 15 can be arranged in each of the bridging bar receiving regions 14, which can be fastened in the respective bridging bar receiving region 14 by means of screws 16. As can be seen from FIG. 2, the bridging bar receiving regions 14a and 14c have a different outer contour compared with 14b and accordingly the individual bridging bars 15a and 15c also have a different outer contour compared with 15b (see also FIGS. 3 and 4 compared with FIGS. 5 and 6). In this way, the bridging bars 15a and 15c cannot be interchanged with 15b, so that it is possible to optimize the individual bridging bars 15a, 15b, 15c for the respective area.

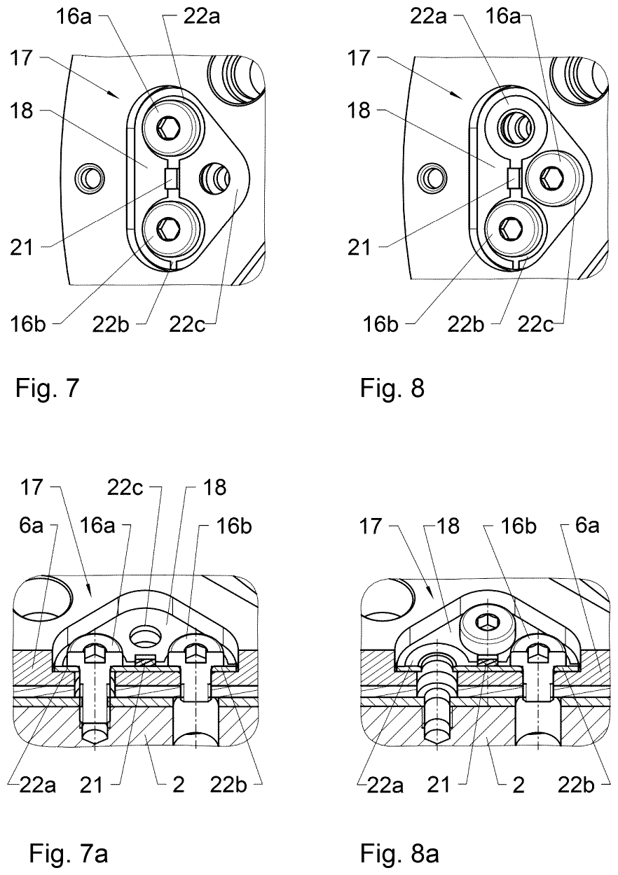

Furthermore, a capacitor bar receiving region 17 (capacitor bar pocket area) is provided in tool segment 6a, in which a capacitor bar 18 (see also FIGS. 7 and 8) can also be fastened by means of screws 16. This condenser bar receiving region 17 is missing in the two other tool segments 6b, 6c. In addition, the capacitor bar 18, and correspondingly also the capacitor bar receiving region 17, is provided with a triangular contour. This will be explained in more detail below.

As can be seen from a combined view of FIGS. 3, 3a, 4 and 4a, the bridging bar 15a is formed differently on its two flat surface sides. Namely, it is provided on a first flat side 19 (FIG. 3) with a non-conductive surface 19m (or a non-conductive surface coating) and a small conductive surface 19n, while it is provided on its opposite side 20 with a conductive surface 20a (FIG. 4) (or with a conductive surface coating). As can be seen in particular from FIGS. 3 and 3a, an electrical connection can be established between the first rotor segment 6a and rotor segment 6b thanks to the bridging bar 15a with its conductive surface 20a facing downwards. Alternatively, the rotor segment 6b can be brought to the potential of the rotor base when the bridging bar 15a is mounted with its conductive surface 20a facing upwards, as shown in FIGS. 4 and 4a. In this position, the conductive upper surface 20a is in contact with the screws, which are also in electrical contact with the rotor base 2, whereby rotor segment 6b is connected to the rotor base via the vias and the lower small conductive surface 19n.

The same applies to the bridging bar 15b, which is shown in FIGS. 5, 5a, 6 and 6a. This also has a non-conductive surface 19p (or surface coating) under the screw heads on one of its two flat surface sides 19, 20, whereas it has a conductive surface 20b (or surface coating) on its opposite flat surface. In the bar mounting position shown in FIGS. 5 and 5a, the rotor segments are therefore electrically connected to each other and in the bar mounting position shown in FIGS. 6 and 6a they are electrically connected to the rotor base via the screws, surface 20b, the vias and the small surface 19q.

Accordingly, by simply turning the relevant bridging bars 15a, 15b (and also 15c; not shown in detail), it is possible for the two rotor segments 6b and 6c to be electrically connected to each other and to the first rotor segment 6a, or for them to be electrically connected to each other and to the rotor base and electrically insulated from the first segment 6a (the insulating layer 13 is also provided for electrical insulation).

The rotor segment 6a is always connected to the electrical signal for blade-conductor contact detection via a rotor coil. The rotor segments 6b and 6c can optionally be electrically connected to either the rotor segment 6a or the rotor base via the bridging bars 15a, 15c. If the bridging bar 15a is installed with its flat conductor layer oriented downwards (FIGS. 3 and 3a), then the corresponding rotor segment 6b is electrically connected to the rotor segment 6a. If the bridging bar 15a is installed with the flat conductor layer facing upwards (FIGS. 4 and 4a), the corresponding rotor segment 6b is electrically insulated from the rotor segment 6a, and the rotor segment 6b is electrically connected to the rotor base via the screws of the bridging bar 15a.

If, as usual, either both rotor segments 6b and 6c are connected to the rotor segment 6a or are operated electrically insulated, the two rotor segments 6b and 6c can be connected to each other via a second bridging bar 15b for safety and electrically insulated against the rotor base (FIGS. 5 and 5a) or connected to each other and to the rotor base (FIGS. 6 and 6a).

The mode of operation of the capacitor bar 18 can be seen in particular from a combined view of FIGS. 7, 7a, 8 and 8a. As can be seen from the figures, the capacitor bar 18 has a capacitor 21 and is provided with an electrically conductive surface coating in two fastening areas 22a, 22b, which in each case also leads to the capacitor 21. In contrast, such an electrically conductive surface coating is missing in the fastening area 22c.

If, as shown in FIGS. 7 and 7a, a screw 16 is screwed into each of the fastening areas 22a, 22b, the respective screws 16 are accordingly also in contact with the capacitor 21 via the electrically conductive surface coating. However, if a screw 16 is screwed into the fastening area 22c, the screw 16 in question is not in electrical contact with the capacitor 21 (see FIGS. 8 and 8a).

Furthermore, the capacitor bar receiving region 17 is designed such that there is an electrical connection to the rotor segment 6a between the threaded area of the screw hole for the short screw 16b of the fastening areas 22b (the short screw 16b being insulated from the rotor base 2), whereas the screw thread of a second fastening area 22a is designed such that there is an electrical connection to the rotor base 2 (the longer screw 16a, however, being insulated from the rotor segment 6a in question). If a screw is screwed into a relevant threaded area/the relevant screw hole, it is accordingly electrically connected to the rotor segment 6a or to the rotor base 2.

It is clear that in the configuration of the capacitor bar receiving region 17 according to FIGS. 7 and 7a, a capacitance 21 is looped in between rotor base 2 and rotor segment 6a. However, this capacitance 21 is missing in the configuration according to FIGS. 8 and 8a. This makes it possible, if the rotor segments 6b and 6c are not electrically connected to the rotor segment 6a, to replace their capacitance to the rotor base by an electrical component so that, for example when using the oscillating circuit measuring method as defined in EP 2 976 818 B1, the resonant frequency does not shift inadmissibly. This again significantly increases the flexibility of the rotary cutting head 1.

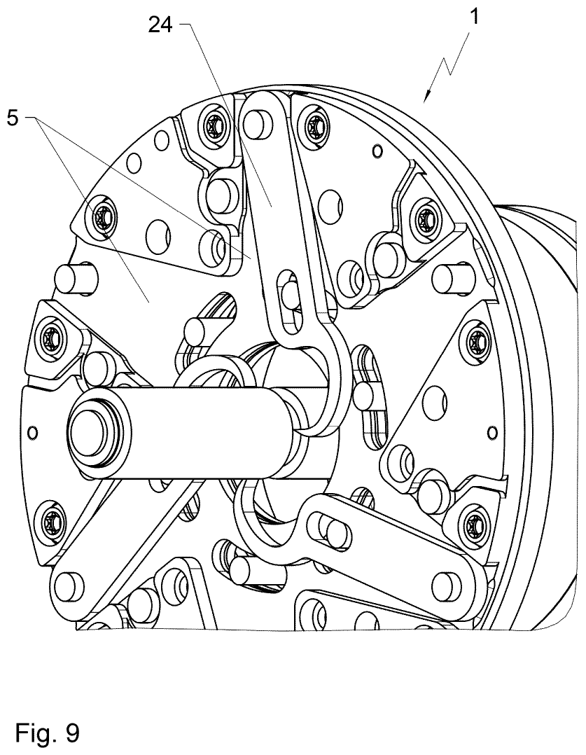

Finally, FIG. 9 shows a further embodiment in which the rotary cutting head 1 is fitted with tools 24 in a different way. In this case, a hook blade 24 is provided in each second tool holding area 5 (and thus in each rotor segment 6 if the tool assembly variant were used on a segmented cutting head). In contrast, the other tool holding area 5 of each rotor segment 6 remains free. This type of mounting of the rotary grinding head 1 is particularly suitable for forming grooves, for example for peeling off (stripping) a non-terminal sheath segment of an insulated cable. In preparation for removing the sheath ring with the hook blades, two incisions are preferably first made in the sheath with a first rotary cutting head at a distance equal to the width of the sheath ring, with preferably only one of the blades having a sharp blade and with the sharp blade being positioned in the at least one tool holding area of the rotor segment, which is electrically connected to the device for detecting contact from an electrical conductor. Preferably, the cable sheath is only cut rotationally to a fraction of its thickness. The rotation of the cutting head is then stopped, and the tools are pressed in until the sharp blade has made contact with the electrical conductor. The tools are then moved back slightly, and the blades are rotated by an angle α around the longitudinal axis of the cable. The blades are then pressed in again. This perforation process of the remaining sheath cross section is repeated until the cable sheath is cut cleanly over the entire circumference. Then, preferably using a second rotary cutting head with three hooked blades, each hooked blade being electrically connected to the device for detecting contact from an electrical conductor, the hooked blades are pressed into the sheath until one of them has made contact with the electrical conductor. These longitudinal cuts are made across the entire width of the ring, after which the three sheath segments are removed in rotation. If a sheath ring width is required that is wider than the thickness of the hook blade, several rings can also be removed in succession in the width of the thickness of a hook blade.

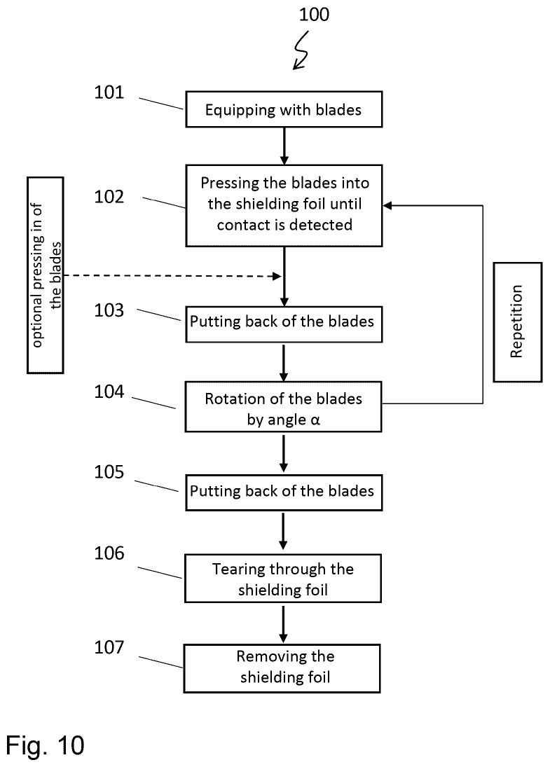

FIG. 10 shows a block diagram 100 of a method for removing a shielding foil with a rotary tool holding apparatus according to the present invention. In order to remove a cable sheath together with the shielding foil of a cable, it would be desirable if the cable sheath and the foil could be cut through without damaging the underlying shield. However, this is hardly possible with rotating cutting blades, as the foil sheath of a cable rarely has a perfectly round cross section. The process described below shows a solution to the problem described.

According to the proposed method 100, in a first step 101 the tool holding areas are equipped with tools, whereby the number of tools is selected such that no electrical contact is created between the rotor segments, whereby only one of the tools has a sharp edge and whereby the tool with the sharp edge is positioned in the at least one tool holding area of the rotor segment which is electrically connected to the device for detecting contact from an electrical conductor.

In a second step 102, a predetermined breaking point is created in the shielding foil by pressing in the tools until the tool with the sharp edge has reached a maximum, predetermined depth or has touched an electrical conductor. Optionally, the tool is pressed in a predetermined distance further after contact detection in order to achieve the desired perforation thickness.

In the next step 103, the tools are put back, which allows the tools to rotate freely by an angle α around the longitudinal axis of the cable (step 104).

Steps 102 to 104 are repeated until a sufficient predetermined breaking point of the shielding foil is reached, preferably until the sum of all angles α is 360° or more. The tools are then put back (step 105), and in the next step 106 the shielding foil is torn through at the predetermined breaking point, for example using a gripper. Finally, in step 107, the shielding foil is removed.

It is advantageous if the cable sheath is rotationally cut to a fraction of its thickness between steps 101 and 102. This reduces the indentation forces. It is also conceivable to remove part or all of the cable sheath before perforation. For most cables, however, it is has been shown to be best to remove the cable sheath together with the shielding foil only after perforation.

The described perforation mode can of course not only be used for foils. It is also suitable, for example, for pulling off a sheath made of very ductile, rubber-like material, where a rotary cut almost down to the conductor is not sufficient, as the remaining residual ring does not tear cleanly when the sheath is pulled off, but stretches out in a rubber-like manner. The perforation mode is also suitable for cables with a thin-walled sheath, for fine-wire stranded cables and non-round cables, and generally for cables where a cut down to the conductor without damaging it is helpful or necessary.

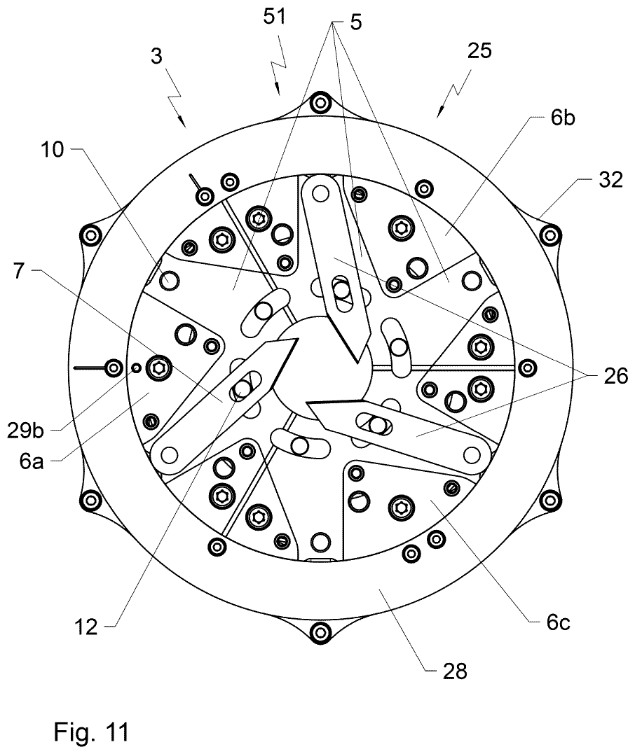

FIGS. 11 to 14 show a second embodiment example of a rotary cutting head 25 in different (partial) views.

In the configuration shown in FIG. 11, the rotary cutting head 25 is equipped with only three tools 7, 26, namely a cutting blade 7 and two blunt blades 26, which serve as support blades. In the configuration shown, the rotary cutting head 25 is particularly suitable for performing a perforation function. Of course, the rotary cutting head 25 can also be used in other configurations. In particular, for example, cutting configurations are conceivable in which a tool is provided in each of the six tool holding areas 5—i.e. a total of six tools are provided (see also FIG. 14).

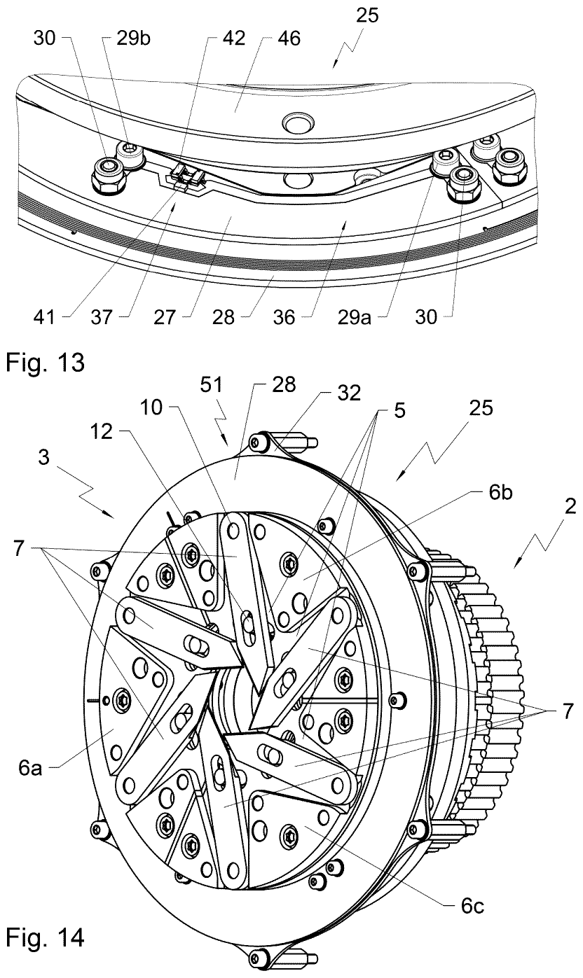

The rotary cutting head 25 is shown in FIG. 11 in a plan view from the front. FIGS. 12a, 12b and 13 each show a partial section of the rotary cutting head 25. The selected sections and the direction of the schematic view are selected differently in FIGS. 12a, 12b and FIG. 13.

An annular flange-like ring is provided in the radially outer circumferential area of the rotary cutting head 25. In the example shown in FIG. 13, it is designed in the form of two half-shells 27 as a printed circuit board made of FR-4. The half-shells are fixed to the rotor base with several fastening screws 29a and to the rotor segment 6a with a screw 29b. A rotor coil circuit board 28 is fixed to the half-shell circuit boards 27 with several screws 30. In this example, this is also designed as a printed circuit board made of FR-4. This can be clearly seen in FIGS. 12a and 12b.

On the rotor coil circuit board 28, several coil windings 31 are also formed as printed conductor tracks (see in particular FIGS. 12a and 12b), which together with the stator coil on the stator coil circuit board 32 (FIG. 11) form a coupling coil device 51. An insulating sleeve 29c made of electrically insulating material (preferably plastic, preferably PEEK) can be inserted between the fastening screws 29b and rotor base 2 for insulation safety. The special screw 35 reinforces the sandwich adhesive bond of the rotor segments, insulating layer and rotor base. The washer 35a between the special screw 35 and the rotor segment is made of a material that is electrically well insulated, is stable under long-term pressure and has the lowest possible dielectric constant, preferably FR-4. The insulating layer between the rotor segments and the rotor base is made of an electrically well insulating material, preferably with a low dielectric constant in order to keep the capacitance between rotor segment and rotor base low, preferably made of a material that is dimensionally stable and easy to bond even under load, such as FR-4.

The one end of the coil windings 31 is electrically connected to the rotor segment 6a via a via 33a in the rotor coil printed circuit board 28 and via the electrical connection path 33 indicated by the thick line in FIG. 12a. The electrical connection path 33 can be formed by electrical conductor tracks, but also additionally or alternatively by an electrically conductive design of the relevant assemblies/assembly areas (e.g. manufacture from an electrically conductive metal).

For the sake of completeness, it should be noted that in a typical basic configuration, the electrical connection between the coupling coil device 51 and the rotor end face 3 is in the form of an electrical connection with only a single rotor segment 6a. Electrical contacting with a further, or with both remaining rotor segments 6b, 6c (embodiment example of the rotary cutting head 25 according to FIG. 11) can be realized, for example, by a suitable contacting arrangement, which is provided in or on the cover disk 4, 50.

FIG. 12b shows a possible design of the electrical connection of the rotor base 2 to the other end of the coil windings 31 via the electrical connection 34 and the via 34a of the rotor coil printed circuit board 28. The rotor base is preferably additionally capacitively connected to the earth potential via large areas and small distances, such as, for example, between the bearing flange 46 and the rotor base 2, and/or radially via concentric rings, such as, for example, between the bearing flange 46 and the bearing spacer ring (not shown). The electrical connection path 34 can be formed by electrical conductor tracks, but also additionally or alternatively by an electrically conductive design of the relevant assemblies/assembly areas (for example manufacture from an electrically conductive metal).

In principle, the half-shell printed circuit boards 27 together with the rotor coil printed circuit board 28 can also be used in conjunction with the rotary cutting head 1 shown in FIG. 2, whereby in a basic configuration only a single rotor segment 6a or a single tool holding area 5 is electrically contacted with (one end of) the coil windings 31. Electrical contacting with a further rotor segment 6b, 6c (or with several further rotor segments 6) can then be achieved by suitable equipping of the bridging bar receiving regions 14.

A contacting (ohmic) electrical contact between the earth potential of the environment and the rotor base 2 and a device for detecting contact from an electrical conductor and the first rotor segment 6a could of course also be implemented via slip rings. However, this would entail the known problems such as wear, soiling and the associated risk of discontinuity in signal transmission. With a sufficiently high quality and/or number of sliding contacts, however, ohmic contacting could be an alternative to inductive coupling.

Since the contact detection in the sense of EP 2 976 818 B1 is carried out with a high-frequency electrical signal, the electrical connection of the device for detecting contact from an electrical conductor to the first rotor segment 6a and that of the earth potential of the environment to the rotor base 2 could of course also be purely capacitive. A resistive coupling would then, as is also the case with inductive coupling, not be present or not necessary, as a sufficiently strong alternating current transmission is still possible at a sufficiently high frequency. The capacitive coupling takes place via sufficiently large surfaces and small distances, for example in the axial direction between the bearing flange 46 and the rotor base 2 and/or radially via concentric rings with a small spacing. Such two concentric rings can be formed, for example, between the bearing spacer ring and the bearing flange 46 without investing additional construction volume.

If the rotor segments 6b and 6c are not electrically connected to the rotor segment 6a, their capacitance to the rotor base can also be partially replaced by a capacitance 41. This is an alternative to the capacitor bar 18 described. For this purpose, corresponding electrical contact areas 37 can be provided on a half-shell conductor plate 27. In the embodiment example shown here, these are provided on one of the two surface sides 36 of the half-shell printed circuit board 27, namely on the surface side 36 facing the rotor base 2.

Incidentally, not only capacitive elements can be looped into the electrical contact areas 37. It is also possible to provide overvoltage protection means here, such as, for example, anti-parallel connected diodes 42 or the like. In this way, excessive voltage peaks, which can occur when electromagnetic interference occurs, for example, can be diverted in an advantageous manner without damaging parts of the electronics for contact detection.

For the sake of completeness only, it is pointed out that a conversion to differently sized capacitances or an additional electrical connection of a further rotor segment to the rotor segment 6a or the like can be realized not only by a mechanical reconstruction, but also by the provision of controllable (electronic) switching elements or the like on the surface 36 of the half-shell printed circuit board. It is also conceivable that the rotor coil printed circuit board 28 is screwed directly to the rotor base 2. The design choice of mounting and contacting the rotor coil printed circuit board via half-shell printed circuit boards 27 offers the advantage in the present design that the rotor coil printed circuit board 28 and the half-shell printed circuit boards 27 can be subsequently mounted, retrofitted or replaced from the front.

FIG. 14 shows a perspective view of the rotary cutting head 25 according to FIG. 11 to further clarify its structure. In particular, the projection area of the rotor coil printed circuit board 28 as a flange-like ring and its positioning relative to the stator coil printed circuit board 32 and the rotor base 2 can be clearly seen. In contrast to FIG. 11, the rotary cutting head 25 is equipped with a different set of tools. In this case, each of the tool holding areas is fitted with a tool, in this case a cutting blade 7. There are therefore six tools in total. For the sake of completeness only, it should be noted that different tools can also be placed in the tool holding areas 5, such as, for example, a cutting blade 7 and five blunt blades 26, or three cutting blades 7 and three blunt blades 26.

It is clear that the embodiment example of a rotary cutting head 25 according to FIGS. 11 to 14 can also be used particularly advantageously for the processes mentioned in the publications WO 2020/065366 A1, WO 2020/119916 A1, WO 2020/119960 A1 and EP 2 976 818 B1 (as well as for other processes not described therein).

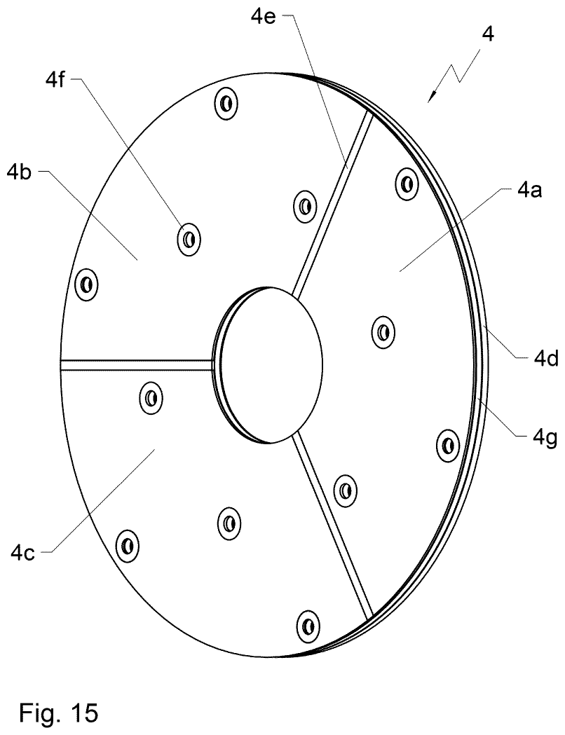

FIG. 15 shows an embodiment of a cover disk 4 that can be used in the embodiment of the cutting head 1 and 25. The cover disk has several functions. Firstly, it has the task of limiting the degrees of freedom of the tools mounted on the cutting head 1, 25. This ensures that the tools do not come loose during use of the tool holding apparatus. The cover disk also protects the adjusting mechanism, in particular the tool holding area 5 and the slotted holes 11, from penetrating objects and provides personal protection, as there is no longer any direct access to the tool holding areas. Secondly, the cover disk has the task of electrically shielding the rotor segments 6a, 6b and 6c and in particular the first rotor segment 6a. For this purpose, the cover disk has a metallic surface on its outer side (the side facing away from the rotor base), which is brought into electrical contact with the rotor base with the aid of screws (not shown here). Thanks to the metallic surface (4d), the tools are protected from external influences that could falsify the detection of a contact between the tools and a conductive part of the cable. Finally, as can be seen in FIG. 15, the metallic surface of the cover disk facing the rotor base is segmented in the same way as the cutting head. The cover disk segments 4a, 4b and 4c of the cover disk are electrically insulated from each other by an insulating material 4e; preferably the insulating material 4e comprises the same adhesive that is used to glue the cover disk parts together, preferably an epoxy adhesive. The cover disk is configured, in particular the position of the screw holes 4f is selected such that it can be mounted on the cutting head in a first position in which the cover disk segments 4a, 4b and 4c are aligned with the rotor segments 6a, 6b and 6c of the cutting head. This creates an equipotential surface around the tools, in particular around the tool of rotor segment 6a, so that the tool assumes the potential of the corresponding rotor segment, shielded from the outside, which ensures robust blade-conductor contact detection. The screw holes 4f are designed large in the rotor segments 6a, 6b and 6c so that no electrical contact can occur between these and the screws for mounting the cover disk. The cover disk can also be mounted on the cutting head in a second position so that electrical contact is established between all rotor segments. The first position is advantageous for the perforation mode, where only one tool is sharp and electrically connected to the device for detecting contact from an electrical conductor, while the others are potential-free (floating) or electrically connected to the rotor base potential. The second position is advantageous if, for example, the insulating cable sheath has to be removed. In this case, it is advantageous if all tools are connected to the device for detecting contact from an electrical conductor. To ensure that the surface 4d is electrically insulated from the cover disk segments 4a, 4b and 4c, the cover disk 4 has an insulating layer 4g.

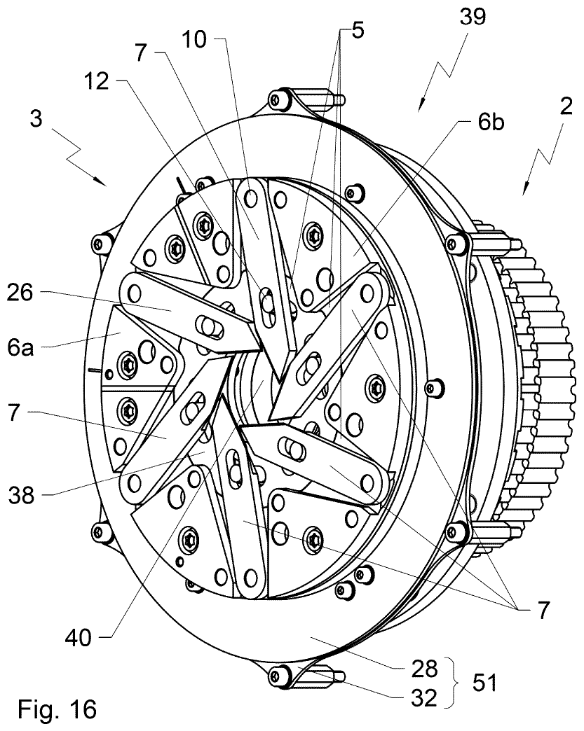

FIG. 16 shows another conceivable design for a rotary cutting head 39 in a perspective view.

It can be clearly seen that an electrically insulating insulation ring 38 is provided radially around the inner receiving hole 40, which serves to receive the end region of the cable to be stripped. This insulating ring 38 serves as a tool pocket base for the various tool holding areas 5 so that electrical insulation of the rotor segments with their associated tool or tools from each other and from the rotor base is always ensured, regardless of the position and number of tools fitted. The insulation ring covers the area of the rotor segments where the individual tool holding areas overlap.

In the present case, the rotary cutting head 39 is designed in such a way that only two different rotor segments 6a, 6b, which are insulated from each other, are created.

Due to its material properties, PEEK (polyether ether ketone) is particularly suitable for the insulation ring, as this material is electrically well insulated, abrasion and pressure resistant and is easy to machine mechanically (together with the rotor segments). In addition, PEEK is also suitable for use at elevated temperatures in operation and for bonding with e.g. polyester resin at elevated temperatures (80 to 100° C.).

Due to the particularly small angular width of the rotor segment 6a, it is possible to perform a perforation process in which only one of the tools 7 can detect an electrical contact with the conductor of the cable to be stripped, whereby all tool holding areas 5 (six in the present case) can nevertheless be equipped with one tool 7. In this case, it is advantageous if the tool in the rotor segment 6a (the segment that is connected to the device for detecting contact with a conductor) has a sharp edge, while the other tools are preferably blunt blades.

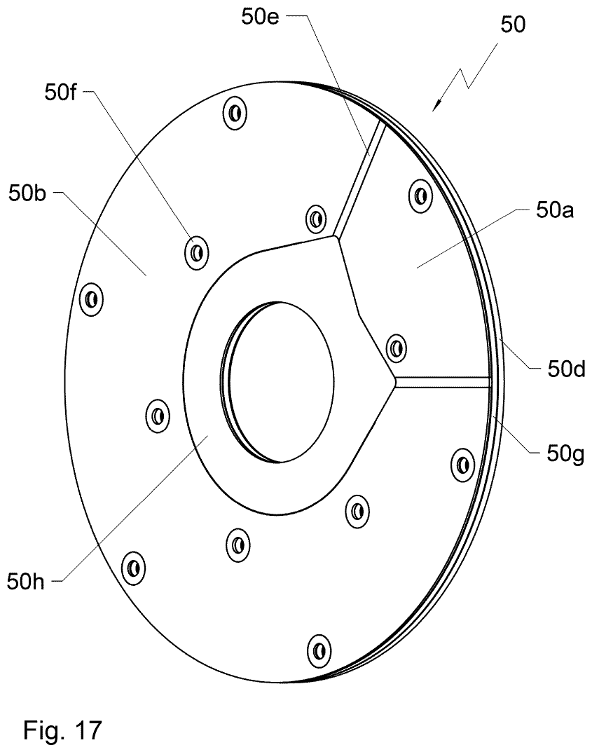

FIG. 17 shows a further embodiment of a cover disk 50, which can preferably be used with the cutting head 39. In contrast to the embodiment shown in FIG. 15, the cover disk only has two cover disk segments 50a and 50b and a cover disk insulation ring 50h. The functions of the cover disk 50 are the same as those of the cover disk 4. Thanks to the cover disk insulation ring 50h, it is ensured in a first fastening position of the cover disk on the cutting head 39 that no contact is made via the cover disk between the rotor segments 6a and 6b of the cutting head by the pivoting of the blades, even if all blades are mounted. However, the cover disk can be mounted on the cutting head in a second position in which electrical contact is made between the rotor segments 6a and 6b. The first position is advantageous for the perforation mode in which only one tool is sharp and electrically connected to the device for detecting contact from an electrical conductor, while the other tools are potential-free (floating) or electrically connected to the rotor base potential. The second position is advantageous if all tools are to be electrically connected to the device for detecting contact from an electrical conductor, such as when the insulating cable sheath has to be removed or a sheath ring has to be removed with hook blades. To ensure that the surface 50d is electrically insulated from the cover disk segments 50a and 50b, the cover disk 50 has an insulating layer 50g.

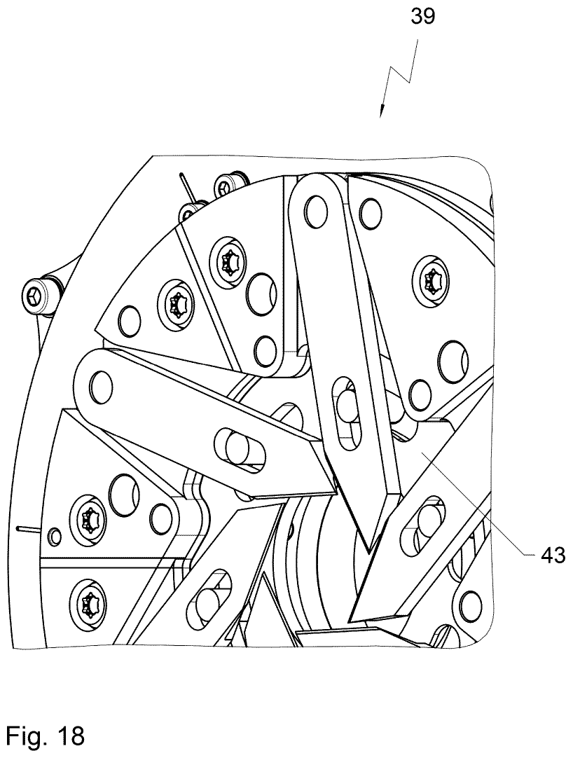

As shown in FIG. 18, the effect of the insulating ring 38 can also be achieved without a ring. In this case, the cutting head 39 advantageously has a recess 43 which is configured in such a way that no contact can be made between the rotor segments while the blades are pivoting.

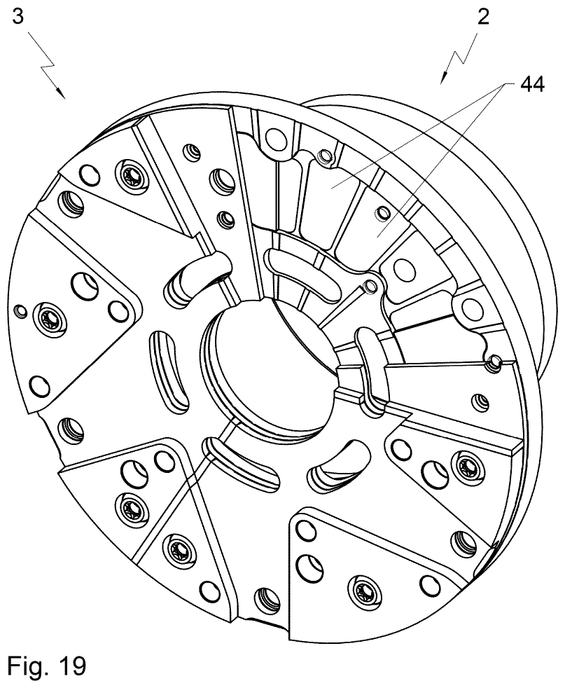

FIG. 19 illustrates an advantageous embodiment of the rotor base 2 and the rotor end face 3, which ensures that the segmented rotor end face 3 is securely glued to the rotor base 2. To ensure that the glue layer thickness is constant and well distributed over the entire bonding area, the rotor base and the rotor segments of the rotor end face are provided with glue pockets 44, preferably 0.2 mm deep. These are designed so that the excess glue (adhesive) can flow away radially. In this way, air pockets are also pressed out radially inwards and outwards from the center. When gluing, therefore, most of the glue and excess glue is applied to approximately the middle radius of the rotor base, so that no strength-reducing air pockets occur.

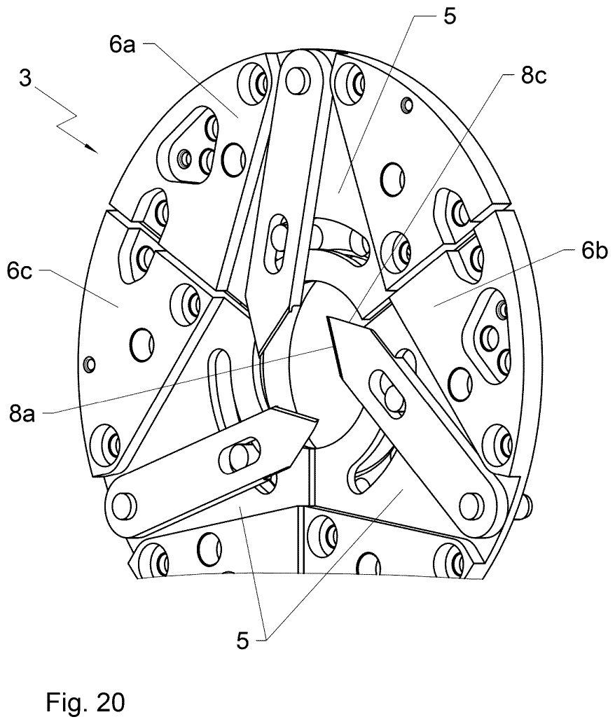

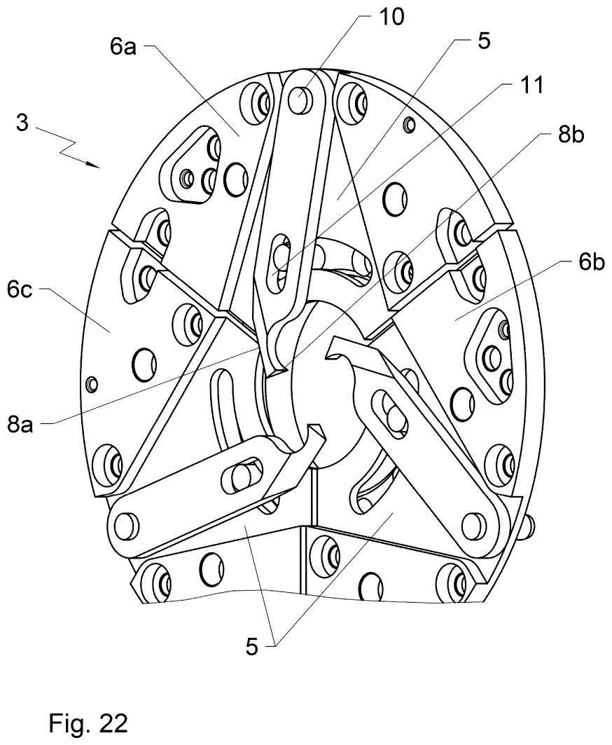

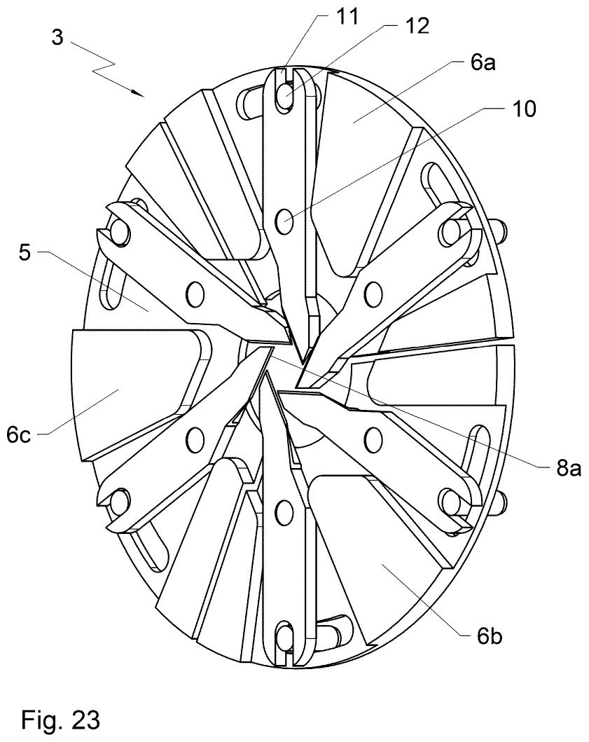

FIGS. 20, 21 and 22 show alternative embodiments for the rotor end face 3. In all of these embodiments, the angular extensions of the tool holding areas 5 of the rotor segments 6a, 6b and 6c are selected such that the tools can have two functional sides 8a and 8b, preferably without contacting the adjacent rotor segments. This means that the tools can, for example, have a sharp edge 8a and a blunt edge 8c, as shown in FIG. 20. It is also possible to provide tools with a sharp edge 8a and an edge 8b in the form of a cutting hook (FIG. 22). As shown in FIG. 21, the elongated holes of the tools can also be provided on the pivot pin.

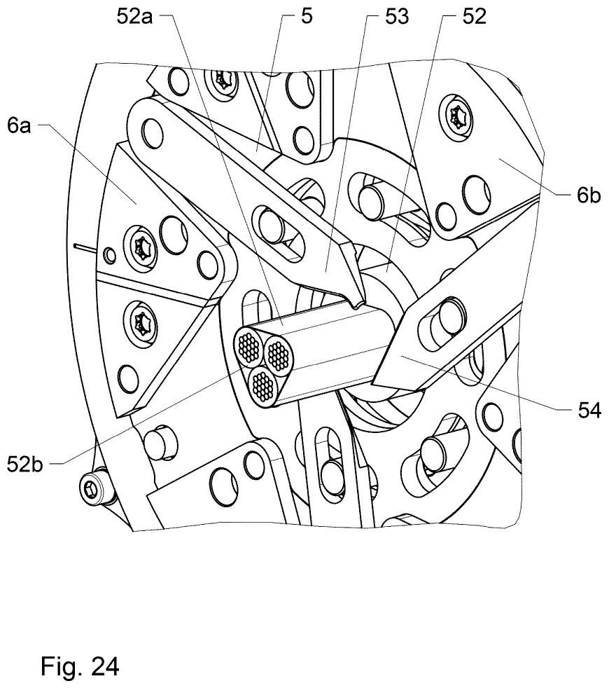

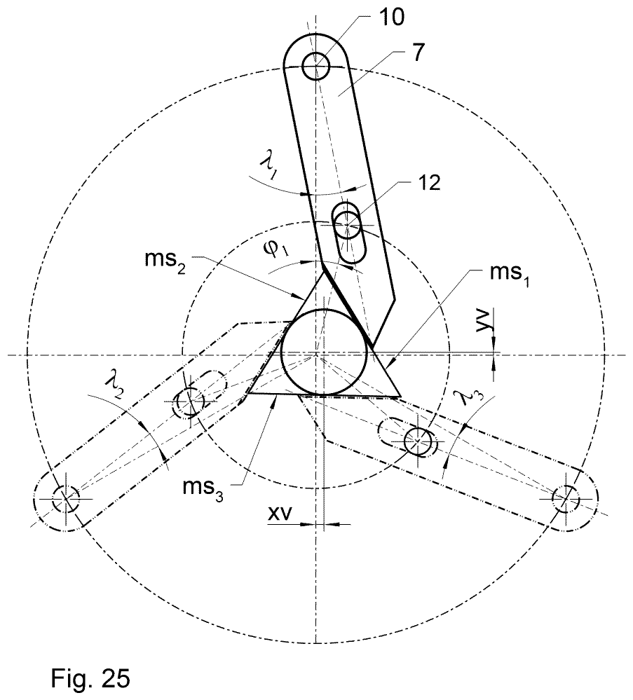

Finally, FIG. 24 shows a possible application example of how an electrically conductive shielding foil of a multicore cable can be perforated with the aid of a segmented rotary rotor end face. In this example, a three-core cable 52 is shown whose foil 52a is to be perforated between the sheath and the conductor insulation 52b. The perforation blade is connected to a device for detecting contact from an electrical conductor via the blade pocket 6a. An inductive sensor or a camera system is used to detect the conductor position in advance and turn the rotor so that the cutting edge contour of the perforating blade 53 fits into the gap between two conductors. The blades are then advanced until contact between the perforation blade and the foil has been detected plus a predetermined perforation path or until a maximum perforation depth has been reached. The blunt support blades 54 only serve to center the cable and do not perforate the foil.

The perforation blade can have various mechanical functions and shapes. It is conceivable, for example, that the blade is only sharp in a limited area, as in the present example only in the area where the cable foil does not rest on the conductor insulation. Instead of a locally protruding sharp cutting edge shape, the perforation tool 53 can be equipped with a needle at the same point, the penetration depth of which is limited by the fact that the needle only protrudes enough beyond the blunt edge of the perforation tool 53 to penetrate the foil. The tool advance can also be controlled via the device for detecting contact from an electrical conductor. To limit the incision, a perforation blade can also have a shoulder so that the cutting edge only protrudes beyond the edge of the tool by the order of magnitude of a foil thickness. The perforation blade could also be constructed in two parts, consisting of a blunt blade holder and a thin blade that protrudes only slightly beyond the edge of the blade holder. The functionalities described for the perforation process, including FIG. 10, apply analogously here.

### LIST OF REFERENCE NUMERALS

1. rotary cutting head according to the invention, tool holding apparatus
2. rotor base
3. rotor end face
4. cover disk
4a, 4b, 4c. cover disk segments
4d. surface of the cover disk
4e. insulating material
4f. screw hole
4g. insulating layer
5. tool holding areas
6. rotor segments
7. cutting blade, tool
8. edge
9. radial center
10. pivot pin
11. elongated hole
12. adjusting pin, adjusting means
13. insulating layer
14. bridging bar receiving region
15. bridging bar
16. screw, fastening means
17. capacitor bar receiving region, pocket area
18. capacitor bar, capacitive element
19. surface of a bridging bar
19m. non-conductive surface
19n. conductive surface
19p. non-conductive surface
19q. conductive surface
20. surface of a bridging bar
20a. conductive surface
20b. conductive surface
21. capacitor, capacitance
22a, 22b, 22c. fastening areas
24. hook blade, tool
25. rotary cutting head according to the invention, tool holding apparatus
26. blunt blade, tool
27. half-shell circuit board
28. rotor coil circuit board
29a. fastening screw
29b. fastening screw
29c. insulation sleeve
30. fastening screw
31. coil windings
32. stator coil circuit board
33. electrical connection path 33a. via
34. electrical connection path
34a. via
35. special screw
35a. washer
36. surface area facing rotor base
37. electrical contact areas
38. insulation ring
39. rotary cutting head according to the invention, tool holding apparatus
40. receiving hole
41. capacitance
42. diodes, overvoltage device
43. recess
44. glue pockets
46. bearing flange
50. cover disk
50a, 50b, 50c. cover disk segments
50d. cover disk surface
50e. insulating material
50g. insulating layer
50h. cover disk insulation ring
51. coupling coil device
52. three-core cable
52a. foil
52b. conductor insulation
53. perforation tool
54. blunt support blade
100. block diagram process
101. equipping with blades
102. pressing the blades into the shielding foil until contact is detected
103. putting back the blades
104. rotation of the blades by angle α
105. resetting the blades
106. tearing through the shielding foil
107. removal of the shielding foil
200. rotary cutting head known from the prior art

1. Rotary tool holding apparatus, comprising a rotor having a rotor base made at least in part of an electrically conductive material, and comprising a segmented rotor end face, whereby at least a first rotor segment made at least in part of an electrically conductive material has one or more tool holding areas, wherein at least the first rotor segment is fastened to the rotor base so as to be electrically insulated from the rotor base and is electrically insulated from at least some of the other rotor segments and wherein the first rotor segment is electrically connected to a device for detecting contact from an electrical conductor.

2. Rotary tool holding apparatus according to claim 1, wherein electrical insulation between the rotor base and at least some of the rotor segments and/or between at least some of the rotor segments among themselves is provided by an insulating layer, which has an electrically insulating material or is formed from an electrically insulating material.

3. Rotary tool holding apparatus according to claim 1, further comprising a cover disk which covers the tool holding areas and comprises an electrically insulating material, whereby the cover disk is configured such that in a first position, in which the first rotor segment is electrically insulated from the other rotor segments, it the cover disk is attachable to the end face of the rotary tool holding apparatus.

4. Rotary tool holding apparatus according to claim 3, wherein the cover disk has on its side facing away from the rotor base a metallic surface electrically connected to the rotor base.

5. Rotary tool holding apparatus according to claim 3, wherein the cover disk is configured such that it can be fastened on the end face of the rotary tool holding apparatus in a second position in which the cover disk electrically connects the first rotor segment to at least one of the other rotor segments.

6. Rotary tool holding apparatus according to claim 3, wherein the cover disk has on its side facing the rotor base a plurality of cover disk segments with a metallic surface, the cover disk segments being electrically insulated from one another and their angular extensions being configured such that, at least in the first position of the cover disk, they do not cause any electrical contact from the first rotor segment to an adjacent rotor segment.

7. Rotary tool holding apparatus according to claim 1, further comprising at least one bridging bar receiving region each formed in two of said rotor segments arranged adjacent to one another, the at least one bridging bar receiving region comprising at least one fastening means receiving regions adapted to reversibly receive fastening means for fastening bridging bars to be received in respective ones of the at least one bridging bar receiving regions.

8. Rotary tool holding apparatus according to claim 7, wherein, in the presence of a plurality of bridging bar receiving regions, the bridging bar receiving regions are at least partially configured differently with respect to their contour, and/or wherein the fastening means receiving region(s) for receiving respective fastening means for fastening respective bridging bars to be received in the respective bridging bar receiving regions are electrically insulated from the rotor base.

9. Rotary tool holding apparatus according to claim 1, further comprising at least one pocket region for receiving a capacitive element, the at least one pocket region being formed in exactly one of the rotor segments which is electrically connected to the device for detecting contact from an electrical conductor.

10. Rotary tool holding apparatus according to claim 9, wherein the at least one pocket region has a plurality of, fastening means receiving regions for receiving fastening means for fastening a capacitive element, a first of the fastening means receiving regions being electrically connected to the respective rotor segment and electrically insulated from the rotor base, and a second of the fastening means receiving regions being electrically connected to the rotor base and electrically insulated from the respective rotor segment.

11. Rotary tool holding apparatus according to claim 1, wherein at least one of the tool holding areas has an adjusting means for adjusting a position of a tool arranged in the relevant tool holding area.

12. Rotary tool holding apparatus according to claim 1, wherein a plurality of tool holding areas is provided, which extend over a substantially similar angular division.

13. Rotary tool holding apparatus according to claim 1, wherein a tool is arranged in at least one of the tool holding areas, said tool comprising an electrically conductive material or being formed from such a material.

14. Rotary tool holding apparatus according to claim 13, wherein a plurality of tools are arranged respectively in a multiplicity of tool holding areas, in a defined fraction of the tool holding areas, or in all tool holding areas, the tools being identical or functionally complementary to one another.

15. Rotary tool holding apparatus according to claim 1, wherein a bridging bar is arranged in at least one of the bridging bar regions, the bridging bar being asymmetrical in that it has a first, electrically connecting insertion position, in which it electrically connects together respective rotor segments lying adjacent to one another, and a second, electrically insulating insertion position, in which it does not electrically connect together the respective rotor segments lying adjacent to one another.

16. Rotary tool holding apparatus according to claim 9, wherein a capacitive element is arranged in the at least one of the pocket region, the capacitive element being asymmetrical in such a way that it has a first insertion position providing a capacitance, in which the capacitance of the capacitive element is connected between two of said fastening means receiving regions, and a second insertion position, which does not provide any capacitance, in which the capacitance of the capacitive element is not connected between the two said fastening means receiving regions.

17. Rotary tool holding apparatus according to claim 1, wherein the device for detecting contact from an electrical conductor comprises a rotor coil and a stator coil, for coupling in and out high-frequency electrical signals, and is arranged radially symmetrically to the rotary tool holding apparatus.

18. Rotary tool holding apparatus according to claim 17, wherein the rotor coil is provided on a rotor coil printed circuit board, the rotor coil printed circuit board being arranged on the rotary tool holding apparatus via two half-shell printed circuit boards and the rotor coil ends being electrically connected to one another via an overvoltage protection device and/or a capacitor for frequency matching of a resonant circuit.

19. Rotary tool holding apparatus according to claim 1, further comprising at least one controllable switching element which establishes or interrupts a controllable, reversible electrical connection between two adjacent ones of said rotor segments arranged relative to one another and/or which introduces or removes a capacitance between a said rotor segment and the rotor base.

20. Cable stripping device, comprising the rotary tool holding apparatus according to claim 1.

21. Method for removing a shielding foil with the rotary tool holding apparatus according to claim 1, comprising the following steps:
a. Equipping the tool holding areas with tools, whereby the number of tools is selected such that no electrical contact is created between the rotor segments, whereby only one of the tools has a sharp edge, and whereby the tool with the sharp edge is positioned in the at least one tool holding area of the first rotor segment electrically connected to the device for detecting contact from an electrical conductor;
b. Creating a predetermined breaking point in the shielding foil by pressing in the tools until the tool with the sharp edge has reached a maximum predetermined depth or contact of an electrical conductor with the tool with the sharp edge is detected;
c. Repeating step b multiple times after the tools have been retracted and rotated by an adjustment angle around the electrical cable;
d. tearing through the shielding foil at the predetermined breaking point;
and
e. Pulling off the shielding foil.

22. Method for removing a shielding foil with a rotary tool holding apparatus according to claim 21, whereby after the tool with the sharp edge has indicated contact with an electrical conductor, the tools are further advanced by a predetermined insertion depth.

23. Method for removing a shielding foil with a rotary tool holding apparatus according to claim 21, said rotary tool holding apparatus further comprising at least one controllable switching element which establishes or interrupts a controllable, reversible electrical connection between two adjacent ones of said rotor segments arranged relative to one another and/or which introduces or removes a capacitance between a said rotor segment and the rotor base; wherein the bridging bars located in the bridging bar regions are brought into their respective insertion position, the bridging bars in their respective insertion position are introduced into the bridging bar regions, or the bridging bars located in the bridging bar regions are removed from the bridging bar regions and/or the respective controllable switching elements are brought into their respective correct switching position.

24. Method according to claim 23, said rotary tool holding apparatus further comprising a plurality of pocket region for receiving respective capacitive elements, the pocket regions, wherein the capacitive elements located in the pocket regions are brought into their respective insertion position, the capacitive elements are brought into the pocket region in their respective insertion position, and/or the controllable switching elements are brought into their respective correct switching position.

25. Method according to claim 24, wherein the capacitive elements located in the pocket region are brought into their first insertion position providing a capacitance and/or the controllable switching elements are brought into a switching position determining the frequency for a coupling coil device.
